(19) United States
(12) Patent Application Publication
(10) Pub. No.: US 2026/0006783 A1
(43) Pub. Date: Jan. 1, 2026

(54) SEMICONDUCTOR MEMORY SYSTEM INCLUDING SEMICONDUCTOR MEMORY DEVICE AND METHOD OF MANUFACTURING THE SAME

(71) Applicant: SK hynix Inc., Icheon-si Gyeonggi-do (KR)

(72) Inventors: Ki Chang JEONG, Icheon-si Gyeonggi-do (KR); Nam Kuk KIM, Icheon-si Gyeonggi-do (KR)

(73) Assignee: SK hynix Inc., Icheon-si Gyeonggi-do (KR)

(21) Appl. No.: 19/317,732

(22) Filed: Sep. 3, 2025

Related U.S. Application Data
(63) Continuation-in-part of application No. 18/594,365, filed on Mar. 4, 2024.
Application No. 18/594,365 is a continuation of application No. 17/147,148, filed on Jan. 12, 2021, now Pat. No. 11,937,421.

(30) Foreign Application Priority Data
Sep. 18, 2020 (KR) 10-2020-0120195

(51) Int. Cl. H10B 41/27; H01L 23/522; H10B 41/10; H10B 43/10; H10B 43/27

(52) U.S. Cl. CPC H10B 41/27; H01L 23/5226; H10B 41/10; H10B 43/10; H10B 43/27

(57) ABSTRACT

A semiconductor memory system includes a semiconductor memory device. The semiconductor memory device includes a first stack, a second stack, and a third stack. The second stack is disposed over the first stack. The second stack includes a plurality of word lines stacked and insulated from each other. The third stack is disposed over the second stack. The third stack includes a second selection line. The channel structure includes a first channel pillar formed through the first stack and the second stack, and a second channel pillar contacting the first channel pillar and formed in the third stack. A diameter of the second channel pillar is smaller than a diameter of the first channel pillar.

### CROSS-REFERENCES TO RELATED APPLICATION

The present application is a Continuation-In-Part Application of U.S. patent application Ser. No. 18/594,365, filed on Mar. 4, 2024, which is a continuation application of U.S. patent application Ser. No. 17/147,148, filed on Jan. 12, 2021, which claims priority under 35 U.S.C. § 119 (a) to Korean application number 10-2020-0120195, filed on Sep. 18, 2020, in the Korean Intellectual Property Office, which applications are incorporated herein by reference in their entirety.

### BACKGROUND

### 1. Technical Field

Various embodiments may generally relate to an electronic system, including but not limited to a semiconductor memory system including a semiconductor memory device and a method of manufacturing the semiconductor memory system.

### 2. Related Art

In order to meet needs of customers such as good performance, low price, and so forth, increasing integration degree of a semiconductor memory device may be advantageous. Because the integration degree of the semiconductor memory device may be an important factor for determining the price of the semiconductor memory device, the increased integration degree may be particularly specified.

For example, when the semiconductor memory device includes a plurality of memory cells, the memory cells may be arranged in a three-dimensional structure to reduce an occupying area of the memory cells. A three-dimensional semiconductor memory device including the three-dimensional structure may be developed.

### SUMMARY

In an embodiment of the present disclosure, a semiconductor memory system may include a first structure and a second structure. The first structure may include a first bonding layer. The second structure may be stacked on the first structure. The second structure may include a memory device layer and a second bonding layer stacked on the memory device layer. The memory device layer of the second structure may comprise a first stack, a second stack, a third stack, and a channel structure. The first stack may include a source selection line. A second stack may be disposed over the first stack. The second stack may include a plurality of word lines stacked and insulated from each other. The third stack may be disposed over the second stack. The third stack may include a drain selection line. The channel structure may include a first channel pillar formed through the first stack and the second stack, and a second channel pillar formed in the third stack and contacting the first channel pillar. A diameter of the second channel pillar may be smaller than a diameter of the first channel pillar.

In an embodiment of the present disclosure, a method of manufacturing a semiconductor memory device may include preparing a first structure including a first substrate, a first circuit layer, and a first bonding layer that are stacked. A second structure including a memory device layer and a second bonding layer formed over the memory device layer may be prepared. The second structure may be stacked over the first structure such that the first bonding layer faces the second bonding layer. The first bonding layer is hybrid bonded to the second bonding layer. The second structure is prepared by forming a first preliminary stack over a second substrate, by alternately and repeatedly stacking a first interlayer insulating layer with a sacrificial layer to form a first selection line; forming a second preliminary stack on the first preliminary stack by alternately and repeatedly stacking insulating interlayers with sacrificial layers to form word lines; forming a first channel pillar through the second preliminary stack and the first preliminary stack; forming a second channel pillar on the first channel pillar, the second channel pillar having a smaller diameter than a diameter of the first channel pillar; forming a gate insulating layer along an outer surface of the second preliminary stack, an outer surface of the first channel pillar, and a sidewall of the second channel pillar; and forming a second selection line on the gate insulating layer, to form a third stack.

In an embodiment, a semiconductor memory system may include a first structure including a first bonding layer and a second structure stacked on the first structure, the second structure including a memory device layer and a second bonding layer. The memory device layer may comprise a first stack including a first selection line; a second stack disposed over the first stack and including a plurality of spaced apart and insulated second selection lines; a third stack disposed over the second stack and including a divided third selection line; and a channel structure including a first channel pillar formed through the first stack and the second stack and a second channel pillar formed in the third stack and contacting the first channel pillar.

### BRIEF DESCRIPTION OF THE DRAWINGS

FIG. 1 is a block diagram illustrating a semiconductor memory device in accordance with an embodiment;

FIG. 2 is a circuit diagram illustrating a memory block of a semiconductor memory device in accordance with an embodiment;

FIG. 3A and FIG. 3B are perspective views illustrating a semiconductor memory device in accordance with an of embodiment;

FIG. 4 is a perspective view illustrating a semiconductor memory device in accordance with an embodiment;

FIG. 5 is a perspective view illustrating a channel pillar of a semiconductor memory device in accordance with an embodiment;

FIG. 6 is an enlarged cross-sectional view of region A of FIG. 4;

FIG. 7 is an enlarged cross-sectional view of region B of FIG. 4;

FIG. 8 is a flowchart illustrating a method of manufacturing a semiconductor memory device in accordance with an embodiment;

FIG. 9 is a flowchart illustrating a method of manufacturing a semiconductor memory device in accordance with an embodiment;

FIG. 10A, FIG. 10B, FIG. 10C, FIG. 10D, FIG. 10E, FIG. 10F, FIG. 10G, FIG. 10H, FIG. 10I, FIG. 10J and FIG. 10K are cross-sectional views of a semiconductor memory cell array manufactured utilizing a method of manufacturing a semiconductor memory cell array in accordance with an of embodiment;

FIG. 11A, FIG. 11B, FIG. 11C, FIG. 11D, FIG. 11E, FIG. 11F, FIG. 11G, FIG. 11H and FIG. 11I are cross-sectional views of a semiconductor memory device manufactured utilizing a method of manufacturing a semiconductor memory device in accordance with an embodiment;

FIG. 12 is a block diagram illustrating a memory system in accordance with an embodiment; and

FIG. 13 is a block diagram illustrating a computing system in accordance with an embodiment.

FIG. 14 is a cross-sectional view of a semiconductor memory system in accordance with an embodiment.

FIG. 15 is a flowchart illustrating a method of manufacturing a semiconductor memory system in accordance with an embodiment.

FIG. 16A through FIG. 16C are cross-sectional views of a semiconductor memory device manufactured utilizing a method of manufacturing a semiconductor memory system in accordance with an embodiment.

FIG. 17 is a cross-sectional view of a semiconductor memory system in accordance with an embodiment.

FIG. 18 is a flowchart of a method of manufacturing a semiconductor memory system in accordance with an embodiment.

FIG. 19 is a cross-sectional view of a semiconductor memory device manufactured utilizing a method of manufacturing a memory system in accordance with an embodiment.

FIG. 20 is a flowchart of a method of manufacturing a second structure including a channel pillar in accordance with an embodiment.

FIG. 21 is a cross-sectional view of a second structure including a channel pillar in accordance with an embodiment.

FIG. 22 is a plan view illustrating a structure of a semiconductor memory device in accordance with an embodiment.

FIG. 23A is a cross-sectional view illustrating a semiconductor memory device in accordance with an embodiment.

FIG. 23B is a cross-sectional view illustrating a semiconductor memory device in accordance with an embodiment.

FIG. 23C is a cross-sectional view illustrating a semiconductor memory device in accordance with an embodiment.

### DETAILED DESCRIPTION

Various embodiments will be described with reference to the accompanying drawings. The drawings are illustrations of various embodiments and intermediate structures. As such, variations from the configurations and shapes of the illustrations as a result, for example, of manufacturing techniques and/or tolerances, are to be expected. Thus, the described embodiments should not be construed as limited to the particular configurations and shapes illustrated herein but may include deviations in configurations and shapes that do not depart from the scope of the present disclosure as set forth in the appended claims.

Terms such as “first” and “second” are used to distinguish between various elements and do not imply size, order, priority, quantity, or importance of the elements. For example, a first element may be referred to as a second element in one example, and the second element may be referred to as a first element in another example.

When one element is identified as “connected” or “coupled” to another element, the elements may be connected or coupled directly or through at least one intervening element between the elements. When two elements are identified as “directly connected” or “directly coupled,” one element is directly connected or directly coupled to the other element without an intervening element between the two elements.

Terms such as “vertical,” “horizontal,” “top,” “bottom,” “above,” “below,” “under,” “over,” “overlap,” “on,” “side,” “upper,” “uppermost,” “lower,” “downward,” “higher,” “high,” “low,” “front,” “back” “row,” “level,” and other terms implying relative spatial relationship or orientation are utilized only for the purpose of ease of description or reference to a drawing and are not otherwise limiting.

The embodiments are described herein with reference to cross-section and/or plan illustrations of idealized embodiments of the present disclosure. However, embodiments should not be construed as limiting the concepts. Although a few embodiments will be shown and described, it will be appreciated by those of ordinary skill in the art that changes may be made in these embodiments without departing from the principles of the present disclosure.

Examples of embodiments may include a semiconductor memory system including a semiconductor memory device for improving operational reliability. The semiconductor memory device may include a non-volatile semiconductor memory device having a three-dimensional structure, for example, a three-dimensional NAND.

The semiconductor memory system including the semiconductor memory device of examples of embodiments is illustrated with reference to drawings. A first direction D1 may indicate an X-direction, a second direction D2 may indicate a Y-direction, and a third direction D3 may indicate a Z-direction. The cross-hatching throughout the figures illustrates corresponding or similar areas between the figures rather than indicating the materials associated with the areas.

Examples of embodiments may include a semiconductor memory device having improved operational reliability.

Examples of embodiments include a method of manufacturing the semiconductor memory device.

According to an embodiment, the semiconductor memory system may include a first channel pillar and a second channel pillar. The first channel pillar may include a cell string. The second channel pillar is formed over the first channel pillar. The second channel pillar may be used as a channel of a drain selection transistor. The second channel pillar may be formed in a split drain selection pattern. Thus, because dummy channel structures might not be required, a chip size in a horizontal direction may be decreased.

Further, by providing the second channel pillar, only third conductive patterns having a single-layered structure separated from each other at a same level may provide sufficient driving capacity required in the drain selection transistor to improve operational reliability.

Furthermore, the drain selection transistor might not have a multi-layered structure so that the chip size in a vertical direction may be reduced and an area of a pass transistor may also be decreased.

Moreover, the second channel pillar may be formed using the mold layer having the mold hole to readily align the first channel pillar and the second channel pillar with each other so that characteristic deterioration caused by a misalignment between the first channel pillar and the second channel pillar may be fundamentally prevented.

As a result, the semiconductor memory device may have an improved integration degree and improved operational reliability.

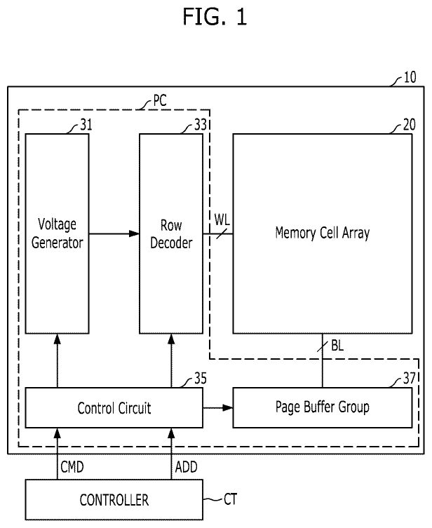

FIG. 1 is a block diagram illustrating a semiconductor memory device in accordance with an embodiment.

Referring to FIG. 1, a semiconductor memory system includes a semiconductor memory device 10 and a controller CT. For example, the semiconductor memory device 10 includes a peripheral circuit PC and a memory cell array 20.

The peripheral circuit PC may be configured to control a program operation for storing data in the memory cell array 20, a read operation for outputting the data from the memory cell array 20, and an erase operation for erasing the data in the memory cell array 20. For example, the peripheral circuit PC may include a voltage generator 31, a row decoder 33, a control circuit 35 and a page buffer group 37.

The memory cell array 20 may include a plurality of memory blocks. The memory cell array 20 may be connected with the row decoder 33 through a plurality of word lines WL. The memory cell array 20 may be connected with the page buffer group 37 through a plurality of bit lines BL.

The control circuit 35 may be configured to control the peripheral circuit PC in response to a command CMD and an address ADD provided from the controller CT.

The voltage generator 31 may be configured to generate various operational voltages including a free erase voltage, an erase voltage, a ground voltage, a program voltage, a verification voltage, a pass voltage, a read voltage, and so forth, used for the program operation, the read operation and the erase operation in response to controls by the control circuit 35.

The row decoder 33 may be configured to select a memory block of the plurality of memory blocks in response to control by the control circuit 35. The row decoder 33 may be configured to apply the operational voltages to the word lines WL connected to the selected memory block.

The page buffer group 37 may be connected to the memory cell array 20 through the bit lines BL. The page buffer group 37 may be configured to temporarily store data, which may be received from an input/output circuit in the program operation, in response to control by the control circuit 35. The page buffer group 37 may sense a voltage or a current of the bit lines BL in the read operation or a verification operation in response to control by the control circuit 35. The page buffer group 37 may select the bit lines BL in response to control by the control circuit 35.

Viewed from a structure of the semiconductor memory device 10, the memory cell array 20 may be arranged side by side with the peripheral circuit PC. Alternatively, the memory cell array 20 may be partially overlapped with the peripheral circuit PC. The memory cell array 20 and the peripheral circuit PC may be 3-dimensionally stacked.

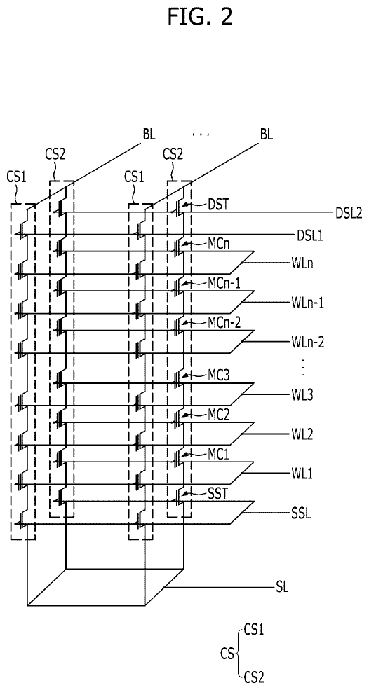

FIG. 2 is a circuit diagram illustrating a memory block of a semiconductor memory device in accordance with an embodiment.

Referring to FIG. 2, a memory block may include a plurality of cell strings CS commonly connected to a source layer SL and a plurality of word lines WL1 to WLn. The cell strings CS1 and CS2 may be connected to a plurality of bit lines BL.

Each of the cell strings CS1 and CS2 may include at least one source selection transistor SST, at least one drain selection transistor DST and a plurality of memory cells MC1 to MCn. The source selection transistor SST may be connected to the source layer SL. The drain selection transistor DST may be connected to the bit line BL. The memory cells MC1 to MCn may be serially connected between the source selection transistor SST and the drain selection transistor DST.

Gates of the memory cells MC1 to MCn may be spaced apart from each other. The gates of the memory cells MC1 to MCn may be connected to stacked word lines WL1 to WLn, respectively. The stacked word lines WL1 to WLn may be insulated from each other. The word lines WL1 to WLn may be arranged between a source selection line SSL and at least two drain selection lines DSL1 and DSL2. The at least two drain selection lines DSL1 and DSL2 may be spaced apart from each other on a same level. For example, the drain selection lines DSL1 and DSL2 are electrically separated and located on a same plane. The drain selection lines DSL1 and DSL2 may also be referred to as drain selection patterns, and the drain selection patterns DSL1 and DSL2 may be selectively driven according to different signals.

A gate of the source selection transistor SST may be connected to the source selection line SSL. A gate of the drain selection transistor DST may be connected to a drain selection line corresponding to the gate of the drain selection transistor DST.

The source layer SL may be connected to a source of the source selection transistor SST. A drain of the drain selection transistor DST may be connected to the bit line BL corresponding to the drain of the drain selection transistor DST.

The cell strings CS include string groups CS1 and CS2 connected to the at least two drain selection lines DSL1 and DSL2, respectively. The cell strings CS connected to one word line and one bit line may be independently controlled by different drain selection lines DSL1 or DSL2. The cell strings CS connected to one selection line may be independently controlled by different bit lines BL. For example, the memory block may include a first drain selection line DSL1 and a second drain selection line DSL2. For example, a first cell string group CS1 is connected to the first drain selection line DSL1 and a second cell string group CS2 is connected to the second drain selection line DSL2.

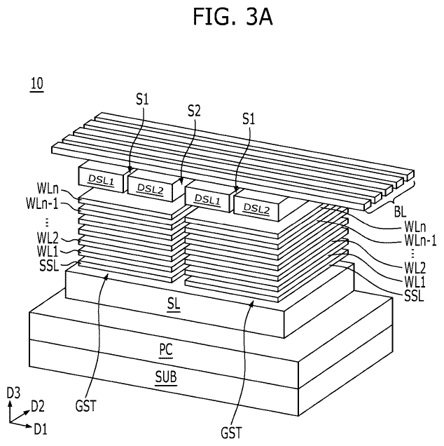

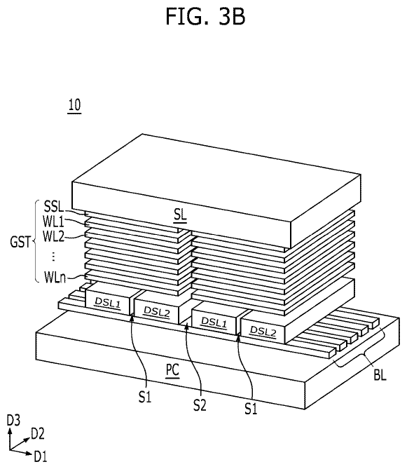

FIG. 3A and FIG. 3B are perspective views illustrating a semiconductor memory device in accordance with an embodiment.

Referring to FIG. 3A, a semiconductor memory device 10 may include a peripheral circuit PC and a plurality of gate stacks GST. The peripheral circuit PC may be arranged on a substrate SUB. The gate stacks GST may be stacked on the peripheral circuit PC.

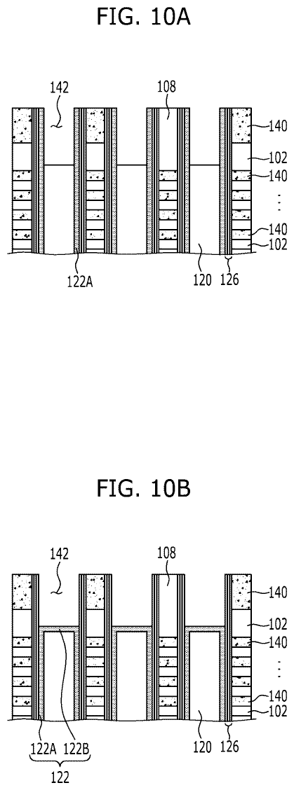

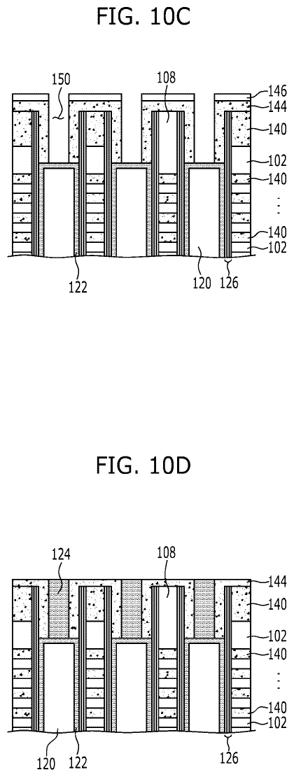

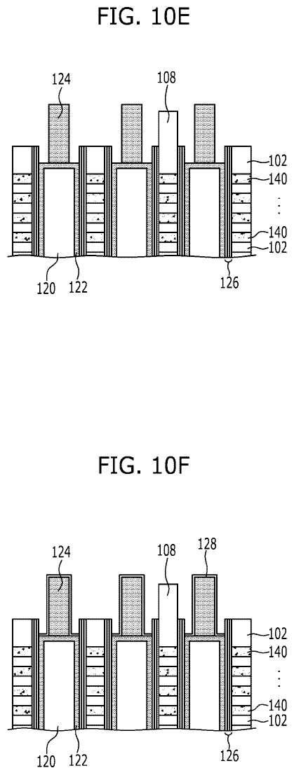

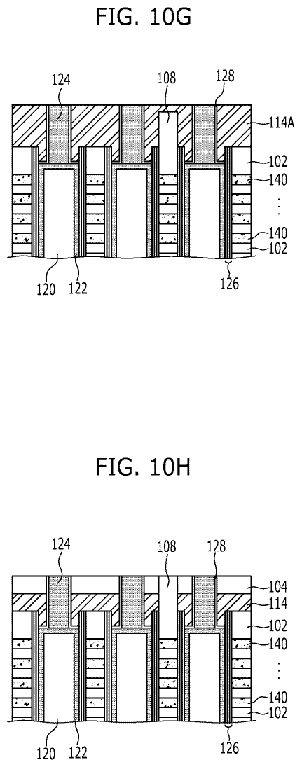

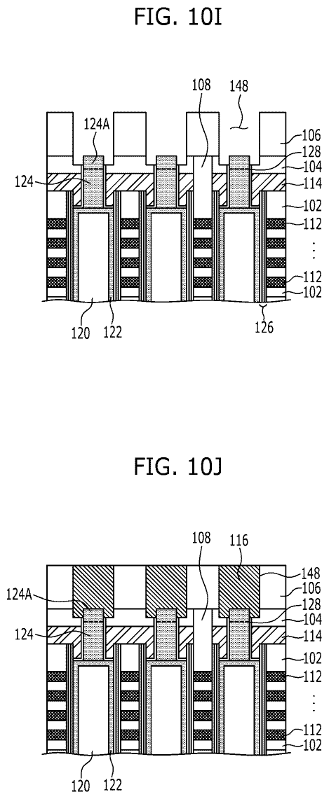

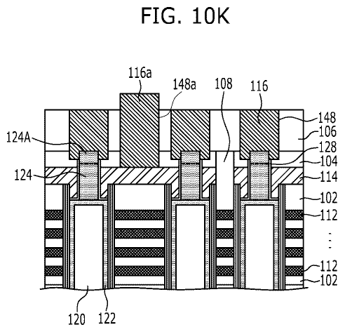

Each of the gate stacks GST includes a source selection line SSL, a plurality of word lines WL1 to WLn and at least two drain selection lines DSL1 and DSL2 that are horizontally spaced apart and selectively driven. The drain selection lines DSL1 and DSL2 are separated by a first slit S1 on a same level. In an embodiment, a level includes a height referenced from a specific location. The first slit S1 includes an isolation layer as described, for example, with reference to FIG. 10A.

The source selection line SSL and the word lines WL1 to WLn extend in a first direction D1 and a second direction D2. For example, the source selection line SSL and the word lines WL1 to WLn are sequentially stacked in a flat rectangular or plate shape.

The word lines WL1 to WLn are spaced apart in a stack in a third direction D3. The word lines WL1 to WLn are arranged between the at least two drain selection lines DSL1 and DSL2 and the source selection line SSL.

The gate stacks GST are separated or divided by a second slit S2. The first slit S1 has a length in the third direction D3 shorter than a length of the second slit S2 in the third direction. The first slit S1 overlaps the word lines WL1 to WLn in the third direction D3. For example, a memory block is bordered by the second slit S2.

The first slit S1 and the second slit S2 may extend in the second direction D2 in a straight line, a zigzag pattern, a wave shape, and so forth. The first slit S1 and the second slit S2 may have varied widths.

The source selection line SSL is closer to the peripheral circuit PC than the drain selection lines DSL1 and DSL2 as shown in FIG. 3A. The semiconductor memory device 10 includes a source layer SL and a plurality of bit lines BL. For example, the source layer SL is arranged between the gate stacks GST and the peripheral circuit PC in FIG. 3A. A position of the source line SL is not limited to this example and may be arranged in various configurations. The plurality of bit lines BL may be arranged further from the peripheral circuit PC than the source layer SL, as shown in FIG. 3A. For example, the plurality of bit lines BL may be arranged over the gate stack GST. The gate stacks GST may be arranged between the bit lines BL and the source layer SL.

Referring to FIG. 3B, the plurality of bit lines BL are arranged closer to the peripheral circuit PC than to the source line SL. The peripheral circuit PC and the gate stack GST may be integrated on different substrates. The bit lines BL may include various conductive layers such as a doped semiconductor layer, a metal layer, a metal alloy layer, and so forth. The source layer SL may include a doped semiconductor layer. For example, the source layer SL may include an n type doped semiconductor layer. The source layer SL is not limited to a doped semiconductor layer, and various conductive materials may be included.

Although not depicted in drawings, the peripheral circuit PC may be electrically connected with the bit lines BL, the source layer SL and the word lines WL1 to WLn via interconnections having various structures.

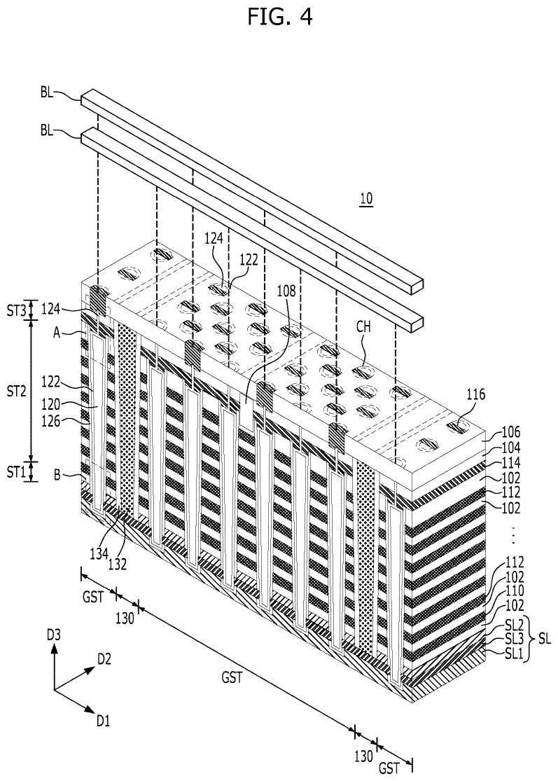

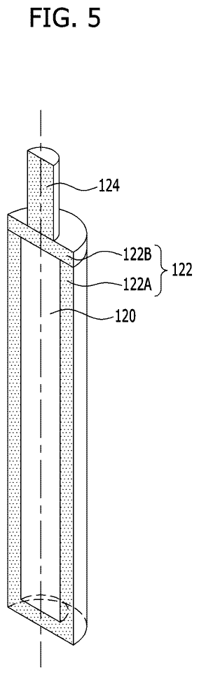

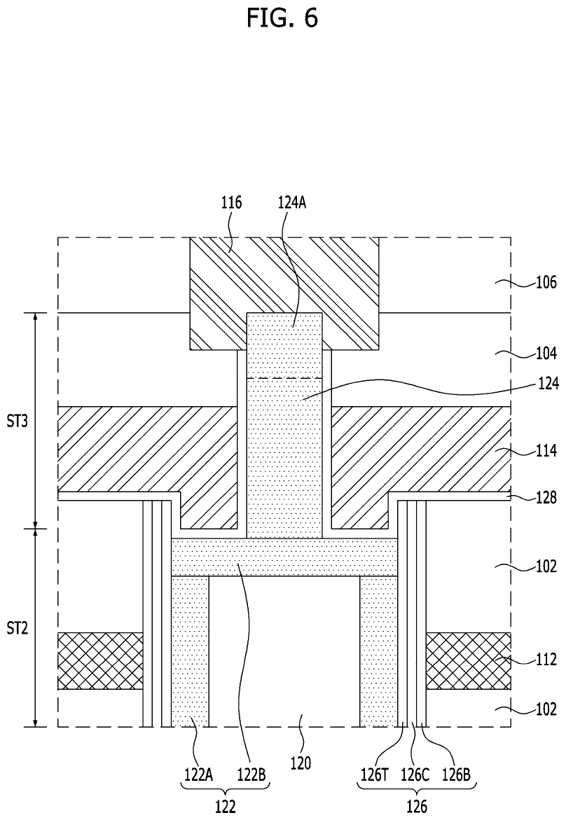

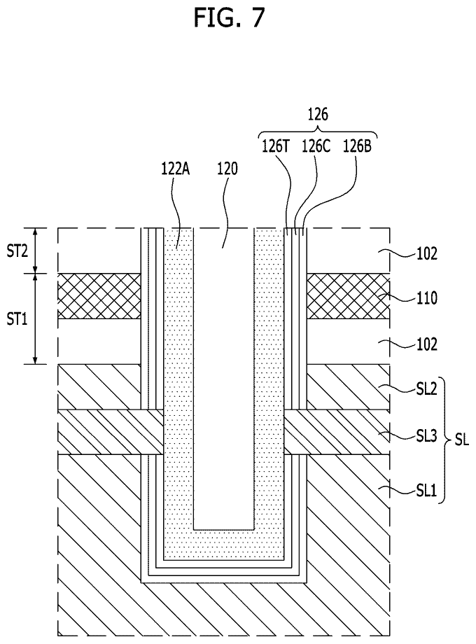

FIG. 4 is a perspective view illustrating a semiconductor memory device in accordance with an embodiment, FIG. 5 is a perspective view illustrating a channel pillar of a semiconductor memory device in accordance with an embodiment, FIG. 6 is an enlarged cross-sectional view of region “A” of FIG. 4, and FIG. 7 is an enlarged cross-sectional view of region “B” of FIG. 4.

Referring to FIG. 4 to FIG. 7, a semiconductor memory device 10 in an embodiment includes a source layer SL, a plurality of gate stacks GST, slit structures 130, a plurality of channel structures CH and a plurality of contact plugs 116. The gate stacks GST may be formed over the source layer SL. The slit structures 130 may be formed between the gate stacks GST. The channel structures CH may be formed through the gate stacks GST. The contact plugs 116 may be formed over the gate stacks GST. The contact plugs 116 may be electrically connected to the channel structures CH, respectively.

Each of the gate stacks GST may be divided by the slit structures 130. For example, the slit structures 130 may be positioned at both sidewalls of each of the gate stacks GST in the first direction D1. Each of the gate stacks GST divided by the slit structures 130 may correspond to one memory block. The source layer SL may be positioned under the gate stacks GST. The bit lines BL may be positioned over the gate stacks GST. Thus, the source layer SL, the gate stacks GST and the bit lines BL may be overlapped with each other.

In an embodiment, the source layer SL may be positioned over the gate stacks GST and the bit lines BL may be positioned under the gate stacks GST. Alternatively, the bit lines BL may be positioned over the gate stacks GST and the source layer SL may be positioned under the gate stacks GST.

The source layer SL may be overlapped with the gate stacks GST. The source layer SL may have a plate or flat rectangular shape extended in the first direction D1 and the second direction D2. For example, the source layer SL may include a first source layer SL1, a second source layer SL2 and a third source layer SL3. The third source layer SL3 may be interposed between the first source layer SL1 and the second source layer SL2. The third source layer SL3 may be electrically connected to a first channel pillar 122 of each of the channel structures CH. The first source layer SL1, the second source layer SL2 and the third source layer SL3 may include doped semiconductor layers. For example, the first source layer SL1, the second source layer SL2 and the third source layer SL3 may include n type doped silicon layers. The third source layer SL3 may have an impurity concentration higher than impurity concentrations of the first and second source layers SL1 and SL2.

In an embodiment, the first source layer SL1, the second source layer SL2 and the third source layer SL3 may include the same conductive material. Alternatively, the first source layer SL1 and the second source layer SL2 may include a same conductive material. The third source layer SL3 interposed between the first source layer SL1 and the second source layer SL2 may include a conductive material different from the conductive material of the first and second source layers SL1 and SL2. The source layer SL is not limited to this example and may include various forms, for example, as a single-layer structure.

The slit structures 130 include the second slit S2 in FIG. 3. Each of the slit structures 130 has a linear shape that extends in the second direction D2. Each of the slit structures 130 may extend in a straight line, a zigzag pattern, a wave shape, and so forth in the second direction D2. For example, a planar structure of the slit structure 130 may include a straight line, a zigzag line or a wave shape, which substantially extend in the second direction D2. The slit structure 130 may have a lower end that extends into the source layer SL in the third direction D3. For example, a bottom surface of the slit structure 130 contacts the third source layer SL3 between the first source layer SL1 and the second source layer SL2.

Each of the slit structures 130 is formed in a trench and includes a slit spacer 134 and a slit layer 132. The trench may have a linear shape extended in the second direction. The slit spacer 134 is formed adjacent to each side of the trench in the first direction D1. For example, the slit spacer 134 is formed on sidewalls of the stacks ST1, ST2, and ST3 adjacent to the trench. The slit layer 132 is formed in the trench. The slit spacer 134 may include an insulation material. The slit layer 132 may include a conductive material.

In an embodiment, the slit layer 132 includes an insulation material.

Each of the gate stacks GST may include a first stack ST1, a second stack ST2 and a third stack ST3 that are sequentially stacked. The first stack ST1 may include at least one first conductive pattern 110 used as a gate of a source selection transistor and a source selection line. The second stack ST2 may include a plurality of second conductive patterns 112 used as gates of memory cells and a plurality of word lines. The third stack ST3 may include at least one third conductive pattern 114 used as at least one gate of at least one drain selection transistor and at least one drain selection line.

Each of the gate stacks GST includes a plurality of stacked conductive patterns. For example, the stacked conductive patterns include the first conductive pattern 110, the second conductive patterns 112 and the third conductive pattern 114. The conductive patterns 110, 112, and 114 are spaced apart. Each of the gate stacks GST include the conductive patterns 110, 112, and 114 alternately stacked with insulating interlayers 102. For example, each of the conductive patterns 110, 112, and 114 may have a flat rectangular or plate shape extended in the first direction D1 and the second direction D2. The conductive patterns 110, 112, and 114 may include a metal material, but is not limited to this example. The insulating interlayers 102 may include an oxide material, but is not limited to this example.

The first conductive pattern 110 of the first stack ST1 may be used as the gate of the source selection transistor SST (see FIG. 2) and the source selection line SSL (see FIG. 2). The first conductive pattern 110 may correspond to the source selection line SSL in FIG. 3. The first conductive patterns 110 of each of the gate stacks GST may have a single-layered structure, and the gate stack GST may include one source selection line SSL. For example, the channel structures CH extending through the gate stack GST are configured to extend to one first conductive pattern 110. Even though the channel structures CH are formed to extend through the first conductive pattern 110, the first conductive pattern 110 located on the gate stack GST surrounded by the slit structures 130 are not disconnected to maintain a same voltage.

In an embodiment, the first stack ST1 includes a plurality of first conductive patterns 110 sequentially stacked and used as gates of the source selection transistors SST and as the source selection lines SSL (see FIG. 2).

Further, in an embodiment, one first conductive pattern 110 of each of the gate stacks GST may be positioned at the same level. Alternatively, at least two conductive patterns 110 of each of the gate stacks GST may be spaced apart from each other on the same level.

For example, the third conductive pattern 114 of the third stack ST3 of the gate stack GST, which is divided into a plurality of third conductive patterns at one or a same level in the third direction D3 by an isolation layer 108 such as the first slit S1 of FIG. 2, are used as the gates of the drain selection transistors and as the drain selection lines DSL1 and DSL2. The third conductive patterns 114 of each of the gate stacks GST may have a single-layered structure. The channel structures CH extend through the third conductive patterns 114. The isolation layer 108 configured to electrically isolate the third conductive patterns 114 from each other corresponds to the first slit S1 in FIG. 3A and FIG. 3B. Sections of each of the third conductive patterns 114 positioned at ends of the isolation layer 108 in the first direction D1 correspond to the first drain selection line DSL1 and the second drain selection line DSL2 in FIG. 3A and FIG. 3B. The isolation layer 108 may include an insulation layer. For example, the isolation layer 108 may include an oxide layer. For example, the first drain selection line DSL1 and the second drain selection line DSL2 are electrically isolated by the isolation layer 108. The first drain selection line DSL1 and the second drain selection line DSL2 may receive different signals or voltages.

Each of the third conductive patterns 114 may have a flat rectangular or plate shape. Each of the third conductive patterns 114 may be downwardly protruded from a region of the third conductive pattern 114 overlapped with the channel structures CH. The downwardly protruded end of the third conductive pattern 114 may be configured to contact a gate insulation layer 128 on the first channel pillar 122. Thus, a length of the second channel pillar 124 in the third direction D3 might not be increased. Further, a channel length of the drain selection transistor may be increased to improve driving capacity.

In an embodiment, each of the gate stacks GST may include the two third conductive patterns 114 spaced apart from each other on the same level. Alternatively, each of the gate stacks GST may include at least two third conductive patterns 114 spaced apart from each other on the same level. In this case, the gate stack GST may include at least one isolation layer 108. In an embodiment, the isolation layer 108, as shown in FIG. 4, may extend from a first insulating layer 102 and past the third conductive pattern 114. In an embodiment, as shown in FIG. 4, a part of the isolation layer 108 may be positioned between the contact plugs 116.

The second conductive patterns 112 among the conductive patterns in the second stack ST2, i.e., the second conductive patterns 112 between the first conductive pattern 110 and the third conductive patterns 114 may be used as the gate of the memory cells and the word line. The second conductive patterns 112 may correspond to the word lines WL1 to WLn in FIG. 3.

The insulating interlayer of each of the gate stacks GST may include first insulating interlayers 102 over or under the first conductive pattern 110 and the second conductive patterns 112, and a second insulating interlayer 104 on the third conductive patterns 114. The first insulating interlayers 102 except for the first insulating interlayer under the third conductive patterns 114 may have substantially the same thickness. The first insulating interlayer 102 under the third conductive patterns 114 may have a thickness greater than that of the remaining first insulating interlayers 102 under the first insulating interlayer 102 that is under the third conductive pattern 114. An upper surface of the second insulating interlayer 104 contacting the third insulating interlayer 106 may be aligned with an upper surface of the slit structure 130 and an upper surface of the isolation layer 108.

The channel structures CH penetrating the gate stack GST may form a plurality of channel rows. The channel structures CH in each of the channel rows may be arranged in a row along an extending direction of the bit lines BL. Each of the bit lines BL may be electrically connected with the channel structures CH via contact plugs 116.

Each of the channel structures CH may be configured to penetrate the gate stack GST. The channel structure CH may have a lower end extended into the source layer SL. Particularly, the lower end of the channel structure CH may be configured to penetrate the second source layer SL2 and the third source layer SL3. A bottom surface of the lower end of the channel structure CH may be positioned in the first source layer SL1.

Each of the channel structures CH may include a core pillar 120, a first channel pillar 122, a memory layer 126, a second channel pillar 124 and a gate insulation layer 128. The first channel pillar 122 may be configured to fully surround the core pillar 120. The memory layer 126 may be configured to surround a side surface and a bottom surface of the first channel pillar 122. The second channel pillar 124 may be formed on the first channel pillar 122. The gate insulation layer 128 may be configured to surround a side surface of the second channel pillar 124.

A planar shape of the core pillar 120 may be a polygonal shape, a circular shape, a tower shape, and so forth. The core pillar 120 may be configured to penetrate the second conductive patterns 112 and the first conductive pattern 110. The core pillar 120 may include a lower end extended into the source layer SL. The core pillar 120 may include an oxide layer.

The first channel pillar 122 may function to provide the source selection transistors and the memory cells with a channel. The first channel pillar 122 may include a first channel layer 122A configured to surround a side surface and a bottom surface of the core pillar 120, and a second channel layer 122B configured to cover an upper surface of the core pillar 120 and an end of the first channel layer 122A. Thus, the first channel layer 122A may have a cylindrical shape and the second channel layer 122B may have a flat rectangular or plate shape. The first channel layer 122A and the second channel layer 122B may include substantially the same material. In an embodiment, the first channel pillar 122, as shown in FIG. 6, may include a first channel layer 122A configured to surround a side surface and a bottom surface of the core pillar 120, and a second channel layer 122B configured to cover an upper surface of the core pillar 120 and an end of the first channel layer 122A.

The second channel pillar 124 may function to provide the drain selection transistor with a channel. Thus, a diameter of the second channel pillar 124 may be determined in accordance with characteristics required in the drain selection transistor. The second channel pillar 124 may be configured to penetrate the third conductive pattern 114. The second channel pillar 124 may be electrically connected to the first channel pillar 122. The diameter of the second channel pillar 124 may be shorter than a diameter of the first channel pillar 122. The diameter of the second channel pillar 124 may be substantially equal to or less than a diameter of the core pillar 120. The second channel pillar 124 may be formed on the second channel layer 122B. A center line of the second channel pillar 124 in a vertical direction may be aligned with a center line of the first channel pillar 122 or the core pillar 120. The center lines of the first channel pillar 122 and the second channel pillar 124 may be indicated by an alternate long and short dash line.

The second channel pillar 124 may include a junction region 124A over the third conductive pattern 114. The junction region 124A may act as the drain of the drain selection transistor. The junction region 124A may be formed by implanting n type impurities into the second channel pillar 124. In an embodiment, the second channel pillar 124, as shown in FIG. 6, may penetrate the uppermost conductive pattern to extend between the uppermost conductive pattern, and the second channel pillar 124 extending past the uppermost conductive pattern may comprise a junction region 124A.

The gate insulation layer 128 configured to surround the side surface of the second channel pillar 124 may be inserted into a region between the second channel pillar 124 and the third conductive pattern 114. The gate insulation layer 128 may be extended to cover an upper surface of the second channel layer 122B. The gate insulation layer 128 may be configured to contact a bottom surface of the third conductive pattern 114. Thus, the gate insulation layer 128 may be inserted between the third conductive pattern 114 and structures under the third conductive pattern 114. The gate insulation layer 128 may function to control a material and a stack structure in accordance with characteristics required in the drain selection transistor. The gate insulation layer 128 may include an oxide layer.

The first channel pillar 122 and the second channel pillar 124 may include substantially the same material. For example, the first channel pillar 122 and the second channel pillar 124 may include at least one semiconductor material. For example, the semiconductor material may include silicon.

The memory layer 126 may include a blocking layer 126B, a charge-trapping layer 126C and a tunnel insulation layer 126T sequentially stacked. The tunnel insulation layer 126T may be configured to contact the first channel layer 122A. The blocking layer 126B may be configured to contact the first conductive pattern 110 and the second conductive patterns 112. The tunnel insulation layer 126T and the blocking layer 126B may include oxide layers. The charge-trapping layer 126C may include a nitride layer.

The memory layer 126 may be configured to surround the bottom surface and the side surface of the first channel pillar 122. The memory layer 126 may include an end extended beyond the first channel pillar 122. Thus, the memory layer 126 may have sidewalls facing with and spaced from a sidewall of the second channel pillar 124. The third conductive pattern 114 downwardly protruded from the region of the third conductive pattern 114 overlapped with the channel structure CH and may be configured to bury a space between the extended memory layer 126 and the second channel pillar 124. In an embodiment, the memory layer 126 may include an end extended past the first channel pillar 122 towards the third conductive pattern 114 in the third direction D3 as shown in FIG. 6. In an embodiment, the memory layer 126 may include an end extended past the first channel pillar 122 to provide side walls that are both facing the second channel pillar 124 and are spaced apart from the second channel pillar 124. In an embodiment, a space between the end of the memory layer 126 extended past the first channel pillar 122 and the second channel pillar 124 is filled the third conductive pattern 114 as shown in FIG. 6.

In an embodiment, the memory layer 126 may include the stacked oxide-nitride-oxide (ONO) structure. Alternatively, the memory layer 126 may include other materials and various stack structure in accordance with characteristics required in the semiconductor memory device.

The contact plugs 116 may be formed on the gate stacks GST. The contact plugs 116 may be electrically connected to the channel structures CH. The contact plugs 116 may be connected between the channel structures CH and the bit lines BL. Particularly, the contact plugs 116 may be positioned in the third insulating interlayer 106 on the gate stacks GST. The bit lines BL may be formed on the third insulating interlayer 106.

Each of the contact plugs 116 may be electrically connected with the second channel pillar 124. An upper end of the second channel pillar 124 may be inserted into a lower end of the contact plug 116. Particularly, the second channel pillar 124 may include the junction region 124A in the upper end of the second channel pillar 124. The junction region 124A may be partially inserted into the lower end of the contact plug 116. By the above-mentioned structure, a contact area between the second channel pillar 124 and the contact plug 116 may be increased to reduce a contact resistance.

When the upper end of the second channel pillar 124 is inserted into the lower end of the contact plug 116, each of the contact plugs 116 may penetrate the third insulating interlayer 106. Further, the lower end of the contact plug 116 may be extended into the second insulating interlayer 104. Therefore, a part of the isolation layer 108 configured to divide the third conductive patterns 114 may be positioned between the contact plugs 116.

According to an embodiment, the semiconductor memory device may include the second channel pillar used as the channel of the drain selection transistor. Thus, the semiconductor memory device might not require dummy channel structures to reduce a chip size in the horizontal direction. Further, only the third conductive patterns having the single-layered structure divided on a same level may provide sufficient driving capacity required in the drain selection transistor to improve operational reliability. Furthermore, the drain selection transistor might not have a multi-layered structure so that the chip size in a vertical direction may be reduced and an area of a pass transistor may also be decreased.

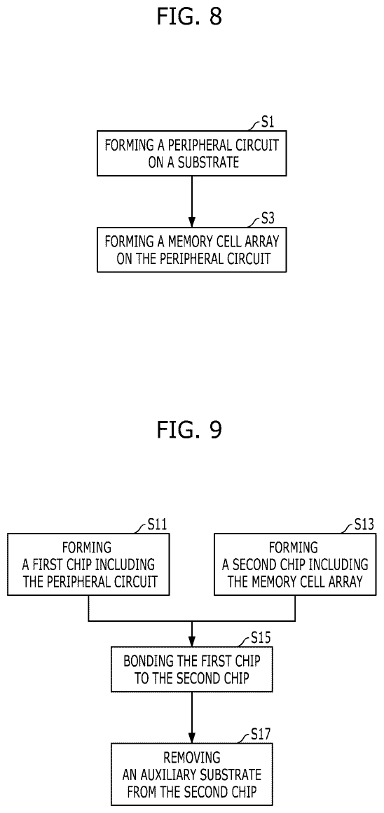

FIG. 8 is a flowchart illustrating a method of manufacturing a semiconductor memory device in accordance with an embodiment. The processes of the flowchart may be performed in a different order and may include fewer or additional processes than described and shown in FIG. 8.

Referring to FIG. 8, a method of manufacturing a semiconductor memory device may include forming S1 a peripheral circuit on a substrate and forming S3 a memory cell array on the peripheral circuit, for example, as described with respect to FIG. 10A to FIG. 10K.

The peripheral circuit may be provided S1 to the substrate. The peripheral circuit may include a plurality of transistors. A source and a drain of each of the transistors may be formed in a region of the substrate. A gate electrode of each of the transistors may be formed on the substrate.

The memory cell array may be formed S3 on the peripheral circuit, which may include forming the source layer SL in FIG. 3, forming the gate stacks GST in FIG. 3, and forming the bit lines BL in FIG. 3.

Although not depicted in drawings, conductive patterns for interconnections may be formed on the peripheral circuit and the memory cell array may be formed on the interconnections.

FIG. 9 is a flowchart illustrating a method of manufacturing a semiconductor memory device in accordance with an of embodiment. The processes of the flowchart may be performed in a different order and may include fewer or additional processes than described and shown in FIG. 9.

Referring to FIG. 9, a method of manufacturing a semiconductor memory device may include forming S11 a first chip including a peripheral circuit, forming S13 a second chip including a memory cell array, bonding S15 the first chip to the second chip, and removing S17 an auxiliary substrate of the second chip.

The peripheral circuit may be provided S11 to a main substrate. The first chip may include first interconnections connected to the peripheral circuit.

The memory cell array may be formed S13 on the auxiliary substrate, for example, as described with respect to FIG. 10A to FIG. 10K, which may include forming the source layer SL in FIG. 3A and FIG. 3B, forming the gate stacks GST in FIG. 3A and FIG. 3B, and forming the bit lines BL in FIG. 3A and FIG. 3B. The second chip may include second interconnections connected to the memory cell array.

In an embodiment, the memory cell array in FIG. 3A and FIG. 3B may include the source layer SL, the gate stacks GST and the bit lines BL sequentially stacked. Alternatively, the memory cell array may include S13 the gate stacks on the bit line without the source layer.

The second chip may be positioned S15 on the first chip to arrange the first interconnections facing the second interconnections. A part of the first interconnections may be bonded to a part of the second interconnections.

The auxiliary substrate may be removed S17 from the second chip to complete the semiconductor memory device including the peripheral circuit and the memory cell array overlapped with each other.

Alternatively, when the memory cell array includes S13 the gate stacks on the bit line without the source layer, the source layer may be connected to the channel structures.

FIG. 10A to FIG. 10K are cross-sectional views of a semiconductor memory cell array manufacturing utilizing a method of manufacturing a semiconductor memory cell array in accordance with an embodiment. The method of manufacturing the memory cell array may be included in the method of FIG. 8 or the method of FIG. 9.

Referring to FIG. 10A, a stack layer may be formed over a substrate. The stack layer may include a first insulating interlayer 102 and a sacrificial layer 140 alternately stacked. The sacrificial layer 140 may be positioned at an uppermost layer of the stack layer. The first insulating interlayer 102 corresponding to an uppermost layer of the first insulating interlayers 102 may have a thickness thicker than a thickness of the remaining first insulating interlayers 102. The sacrificial layer 140 corresponding to the uppermost layer of the sacrificial layers 140 may have a thickness thicker than a thickness of the remaining sacrificial layers 140. The first insulating interlayer 102 may include an oxide layer and the sacrificial layers 140 may include a nitride layer.

An isolation layer 108 may be formed to extend through the uppermost first insulating interlayer 102 and the uppermost sacrificial layer 140. The isolation layer 108 may correspond to the first slit S1 in FIG. 3A or FIG. 3B. The isolation layer 108 may include an insulation layer. For example, the isolation layer 108 may include an oxide layer.

A plurality of channel holes 142 may be formed through the stack layer using a hard mask pattern.

A memory layer 126 may be formed on a surface of each of the channel holes 142. The memory layer 126 may include a blocking layer 126B, a charge-trapping layer 126C and a tunnel insulation layer 126T sequentially stacked. The blocking layer 126B and the tunnel insulation layer 126T may include an oxide layer and the charger-trapping layer 126C may include a nitride layer.

A first channel layer 122A may be formed on the memory layer 126. The first channel layer 122A on the surface of the channel hole 142 over the memory layer 126 may have a cylindrical shape. The first channel layer 122A may include a semiconductor layer. For example, the first channel layer 122A may include a silicon layer.

A core pillar 120 may be formed on the first channel layer 122A to fill the channel hole 142 with the core pillar 120. The core pillar 120 may include an oxide layer.

A recess etch process may be performed on the core pillar 120 on an upper end of the channel hole 142 to reduce a height of the core pillar 120. An etched depth of the recess etch process may be substantially equal to or less than a sum of the thickness of the uppermost first insulating interlayer 102 and the thickness of the uppermost sacrificial layer 140.

Referring to FIG. 10B, a second channel layer 122B may be formed on the core pillar 120 to cover an end of the first channel layer 122A. The second channel layer 122B may include a material substantially the same as that of the first channel layer 122A. For example, the second channel layer 122B may include a silicon layer. The second channel layer 122B may be formed by forming a silicon layer in the channel hole 142, and by performing a recess etching process on the silicon layer to reduce a thickness of the silicon layer in the channel hole 142. Thus, the second channel layer 122B may have a flat rectangular or plate shape having a planar shape corresponding to a planar shape of the channel hole 142.

Therefore, a first channel pillar 122 including the first channel layer 122A and the second channel layer 122B may be formed. The first channel layer 122A may be configured to surround a side surface and a bottom surface of the core pillar 120. The second channel layer 122B may be configured to cover an upper surface of the first channel layer 122A.

After forming the first channel pillar 122, a memory layer 126 exposed through an upper end of the channel hole 142 may be etched.

Referring to FIG. 10C, a mold layer 144 may be formed on upper surface of a structure with the first channel pillar 122. The mold layer 144 may include a material substantially the same as that of the sacrificial layer 140. For example, the mold layer 144 may include a nitride layer.

A hard mask may then be formed on the mold layer 144. The mold layer 144 may be etched using the hard mask as an etch barrier to form a mold hole 150 configured to partially expose the second channel layer 122B. Because the mold layer 144 may be extended along a profile of the upper surface of the structure with the first channel pillar 122, the mold hole 150 may be self-aligned with the first channel pillar 122.

Referring to FIG. 10D, a second channel pillar 124 may be formed on the second channel layer 122B. The second channel pillar 124 may include a material substantially the same as that of the first channel pillar 122. Thus, the second channel pillar 124 may include a silicon layer. The second channel pillar 124 may be formed by forming a silicon layer on the entire surface of the structure to fill up the mold hole 150, and planarizing the silicon layer until an upper surface of the mold layer 144 may be exposed.

Thus, the second channel pillar 124 may be formed on the first channel pillar 122. The second channel pillar 124 may have a center line aligned with a center line of the first channel pillar 122 or the core pillar 120 in the third direction D3.

Referring to FIG. 10E, after removing the mold layer 144, the uppermost sacrificial layer 140 may then be removed. Because the mold layer 144 and the uppermost sacrificial layer 140 may include the same material, the mold layer 144 and the uppermost sacrificial layer 140 may be simultaneously removed by one etching process.

Further, the memory layer 126 on sidewalls of the mold layer 144 and the uppermost sacrificial layer 140 may also be removed together with the mold layer 144 and the uppermost sacrificial layer 140.

Referring to FIG. 10F, a gate insulation layer 128 may be formed on surfaces of the first channel pillar 122 and the second channel pillar 124 exposed by removing the mold layer 144 and the uppermost sacrificial layer 140. The gate insulation layer 128 may include an oxide layer. The gate insulation layer 128 may be formed by a deposition process, an oxidation process, and so forth. When the gate insulation layer 128 may be formed by the oxidation process, the gate insulation layer 128 may be selectively formed on only the surfaces of the first channel pillar 122 and the second channel pillar 124. When the gate insulation layer 128 is formed by the deposition process, the gate insulation layer 128 is formed along the entire surface of the structure including any exposed areas of the first channel pillar 122, the second channel pillar 124, the memory layer 126, and the insulating interlayer 102.

In an embodiment, the method may include forming the gate insulation layer by the oxidation process. The oxidation process may include a thermal treatment process under an oxygen atmosphere, an oxygen radical process under plasma atmosphere, and so forth.

FIG. 6 shows the gate insulation layer 128 formed by the deposition process.

Referring to FIG. 10G, a conductive layer 114A may be formed in a space between the second channel pillars 124. The conductive layer 114A may be formed in a space between the second channel pillar 124 and the uppermost first insulating interlayer 102 as well as the space between the second channel pillars 124.

The conductive layer 114A may be formed by depositing the conductive layer 114A on an entire surface of a structure with the second channel pillar 124, and planarizing the conductive layer 114A until an upper surface of the second channel pillar 124 may be exposed. The gate insulation layer 128 may be partially exposed by the planarization process to expose the upper surface of the second channel pillar 124.

Referring to FIG. 10H, the conductive layer 114A may be etched-back to form third conductive patterns 114. Upper surfaces of the third conductive patterns 114 are positioned under the upper surface of the second channel pillar 124. Thus, the upper surface and upper sidewall of the second channel pillar 124 are exposed by the third conductive patterns 114. The third conductive patterns 114 are horizontally divided or separated by the isolation layer 108. The third conductive patterns 114 may correspond to the drain selection lines DSL1 and DSL2 in FIG. 3.

A second insulating interlayer 104 may be formed on the third conductive patterns 114. The second insulating interlayer 104 may then be planarized. An upper end of the second channel pillar 124, which may be damaged by the etch-back process for forming the third conductive patterns 114, may also be removed by the planarization process. The upper surface of the second channel pillar 124, the upper surface of the second insulating interlayer 104 and the upper surface of the isolation layer 108 may be substantially coplanar with each other by the planarization process. The second insulating interlayer 104 may include an oxide layer.

Referring to FIG. 4 and FIG. 10I, the sacrificial layer 140 may then be removed by a process for forming the slit structures 130. A conductive material may be formed in a space formed by removing the sacrificial layer 140 to form a first conductive pattern 110 and second conductive patterns 112.

Therefore, a plurality of gate stacks GST divided by the slit structure 130 may be formed.

A third insulating interlayer 106 may be formed on the gate stacks GST and the slit structures 130. The third insulating interlayer 106 may include an oxide layer.

The third insulating interlayer 106 and the second insulating interlayer 104 are etched using a hard mask pattern as an etch barrier to form a plurality of contact holes 148 configured through which an upper region of the second channel pillar 124 is exposed. For example, the upper region of the second channel pillar 124 includes an upper surface and upper sidewall extending from the upper surface of the second channel pillar 124.

In an embodiment, impurities are implanted into the upper region of the second channel pillar 124 exposed through the contact hole 148. The upper region of the second channel pillar 124 is thermally treated to form a junction region 124A in the upper region of the second channel pillar 124. The impurities may include n type impurities. The junction region 124A corresponds to a drain of a drain selection transistor.

Referring to FIG. 10J, a plurality of contact plugs 116 are formed in the contact holes 148. The contact plugs 116 are configured to connect the second channel pillar 124 with the bit lines. The contact plug 116 may be referred to as a contact pad, a bit line contact pad, or a capping pad.

The upper region of the second channel pillar 124 is inserted into a lower end of the contact plug 116 to increase a contact area between the second channel pillar 124 and the contact plug 116, thereby reducing a contact resistance. Because the upper region of the second channel pillar 124 is disposed within the lower end of the contact plug 116, a part of the isolation layer 108 configured to divide the third conductive patterns 114 is positioned between the contact plugs 116.

In an embodiment, referring to FIG. 10I to FIG. 10K, when the contact holes 148 are formed, a drain selection contact hole 148a is formed, through which the third conductive patterns 114 are exposed. A drain selection line contact plug 116a is formed in the drain selection contact hole 148a simultaneously with the contact plug 116 in an embodiment. The third conductive patterns 114, corresponding to the drain selection lines DSL1 and DSL2 or drain selection patterns, which are isolated by the isolation layer 108, receive a drain selection voltage through the drain selection line contact plugs 116a. For example, the contact plugs 116 and the drain selection line contact plugs 116a may include a doped poly silicon material. Although not illustrated in detail in the drawings, the drain selection line contact plugs 116a contact the third conductive lines 114 divided by the isolation layer 108. Thus, the isolation layer 108 is positioned between the drain selection line contact plugs 116a.

Therefore, the memory cell array in FIG. 4 including the gate stacks GST, the slit structures 130, the channel structures CH, and the contact plugs 116 is formed. The slit structures 130 are formed between the gate stacks GST. The channel structures CH extend through the gate stack GST. The contact plugs 116 and the drain selection line contact plugs 116a may be formed over the gate stacks GST. The contact plugs 116 are electrically connected to the channel structures CH. The drain selection line contact plugs 116a are electrically connected to the drain selection lines 114, respectively.

According to an embodiment, the second channel pillar 124 may be formed using the mold layer 144 with the mold hole 150.

Thus, the first channel pillar 122 and the second channel pillar 124 may be readily aligned with each other so that characteristic deteriorations caused by a misalignment between the first and second channel pillars 122 and 124 may be fundamentally prevented.

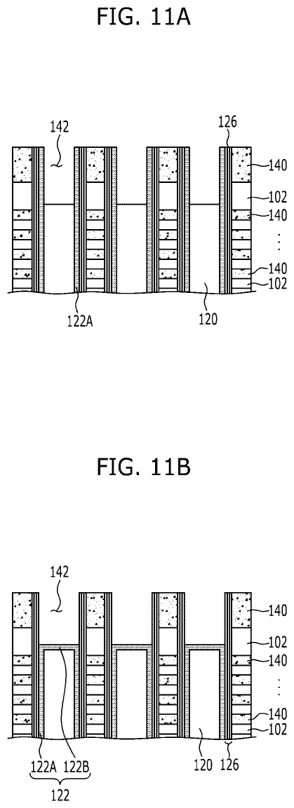

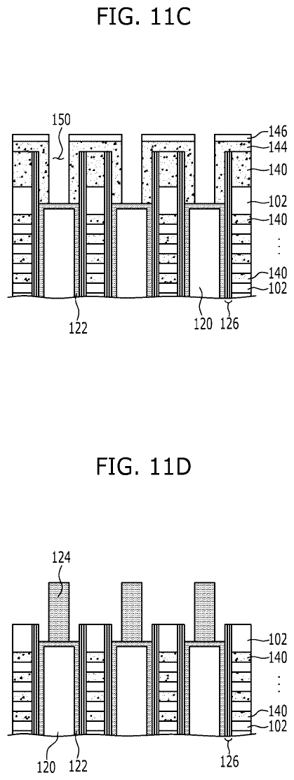

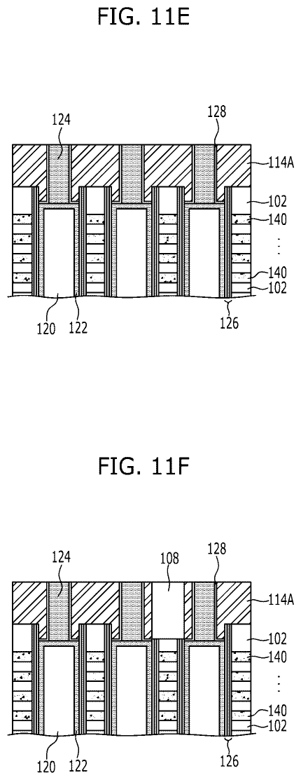

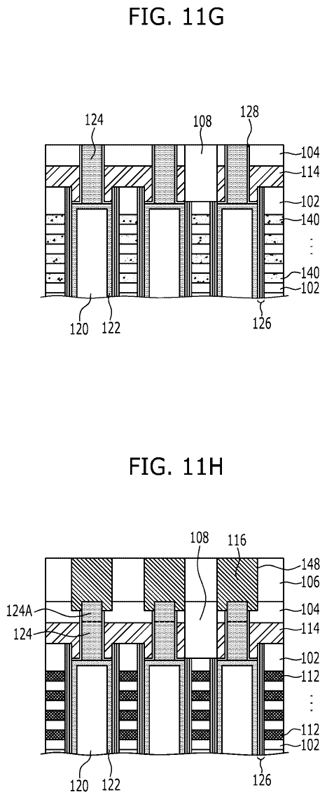

FIG. 11A to FIG. 11H are cross-sectional views of a semiconductor memory device manufactured utilizing a method of manufacturing a semiconductor memory device in accordance with an embodiment. FIG. 11A to FIG. 11H a memory cell array of the semiconductor memory device. The method of manufacturing the memory cell array may be included in in the method of FIG. 8 or in the method of FIG. 9.

Referring to FIG. 11A, a stack layer may be formed on a substrate. The stack layer may include a first insulating interlayer 102 alternately stacked with a sacrificial layer 140 multiple times. The sacrificial layer 140 may be positioned at an uppermost layer of the stack layer. The first insulating interlayer 102 corresponding to an uppermost layer of the first insulating interlayers 102 may have a thickness thicker than a thickness of the remaining first insulating interlayers 102. The sacrificial layer 140 corresponding to the uppermost layer of the sacrificial layers 140 may have a thickness thicker than a thickness of the remaining sacrificial layers 140. The first insulating interlayer 102 may include an oxide layer and the sacrificial layers 140 may include a nitride layer.

A plurality of channel holes 142 may be formed through the stack layer using a hard mask pattern.

A memory layer 126 may be formed on a surface of each of the channel holes 142. The memory layer 126 may include a blocking layer 126B, a charge-trapping layer 126C and a tunnel insulation layer 126T sequentially stacked. The blocking layer 126B and the tunnel insulation layer 126T may include an oxide layer and the charger-trapping layer 126C may include a nitride layer.

A first channel layer 122A may be formed on the memory layer 126. The first channel layer 122A on the surface of the channel hole 142 over the memory layer 126 may have a cylindrical shape. The first channel layer 122A may include a semiconductor layer. For example, the first channel layer 122A may include a silicon layer.

A core pillar 120 may be formed on the first channel layer 122A to fully fill the channel hole 142 with the core pillar 120. The core pillar 120 may include an oxide layer.

A recess etch process may be performed on the core pillar 120 on an upper end of the channel hole 142 to reduce a height of the core pillar 120. An etched depth of the recess etch process may be substantially equal to or less than a sum of the thickness of the uppermost first insulating interlayer 102 and the thickness of the uppermost sacrificial layer 140.

Referring to FIG. 11B, a second channel layer 122B may be formed on the core pillar 120 to cover an end of the first channel layer 122A. The second channel layer 122B may include a material substantially the same as that of the first channel layer 122A. For example, the second channel layer 122B may include a silicon layer. The second channel layer 122B may be formed by forming a silicon layer in the channel hole 142, and by performing a recess etching process on the silicon layer to reduce a thickness of the silicon layer in the channel hole 142. Thus, the second channel layer 122B may have a flat rectangular or plate shape having a planar shape corresponding to a planar shape of the channel hole 142.

Therefore, a first channel pillar 122 including the first channel layer 122A and the second channel layer 122B may be formed. The first channel layer 122A may be configured to surround a side surface and a bottom surface of the core pillar 120. The second channel layer 122B may be configured to cover an upper surface of the first channel layer 122A.

After forming the first channel pillar 122, a memory layer 126 exposed through an upper end of the channel hole 142 may be etched.

Referring to FIG. 11C, a mold layer 144 may be formed on upper surface of a structure with the first channel pillar 122. The mold layer 144 may include a material substantially the same as that of the sacrificial layer 140. For example, the mold layer 144 may include a nitride layer.

A hard mask may then be formed on the mold layer 144. The mold layer 144 may be etched using the hard mask as an etch barrier to form a mold hole 150 configured to partially expose the second channel layer 122B. Because the mold layer 144 may be extended along a profile of the upper surface of the structure with the first channel pillar 122, the mold hole 150 may be self-aligned with the first channel pillar 122. For example, a center area of the first channel pillar 122 is exposed through the mold hole 150.

Referring to FIG. 11D, a second channel pillar 124 may be formed on the second channel layer 122B. The second channel pillar 124 may include a material substantially the same as that of the first channel pillar 122. Thus, the second channel pillar 124 may include a silicon layer. The second channel pillar 124 may be formed by forming a silicon layer on the entire surface of the structure to fill up the mold hole 150, and planarizing the silicon layer until an upper surface of the mold layer 144 may be exposed.

Thus, the second channel pillar 124 may be formed on the first channel pillar 122. The second channel pillar 124 may have a center line aligned with a center line of the first channel pillar 122 or the core pillar 120 in the third direction D3 corresponding to a vertical direction.

After removing the mold layer 144, the uppermost sacrificial layer 140 may then be removed. Because the mold layer 144 and the uppermost sacrificial layer 140 may include the same material, the mold layer 144 and the uppermost sacrificial layer 140 may be simultaneously removed by one etching process.

Further, the memory layer 126 on sidewalls of the mold layer 144 and the uppermost sacrificial layer 140 may also be removed together with the mold layer 144 and the uppermost sacrificial layer 140.

Referring to FIG. 11E, a gate insulation layer 128 may be formed on surfaces of the first channel pillar 122 and the second channel pillar 124 exposed by removing the mold layer 144 and the uppermost sacrificial layer 140. The gate insulation layer 128 may include an oxide layer. The gate insulation layer 128 may be formed by a deposition process, an oxidation process, and so forth. When the gate insulation layer 128 may be formed by the oxidation process, the gate insulation layer 128 may be selectively formed on only the surfaces of the first channel pillar 122 and the second channel pillar 124. In contrast, when the gate insulation layer 128 may be formed by the deposition process, the gate insulation layer 128 may be formed on the entire surface of the structure.

In an embodiment, the method may include forming the gate insulation layer by the oxidation process. The oxidation process may include a thermal treatment process under an oxygen atmosphere, an oxygen radical process under plasma atmosphere, and so forth.

FIG. 6 may show the gate insulation layer 128 formed by the deposition process.

Referring to FIG. 11E, a conductive layer 114A may be formed in a space between the second channel pillars 124. The conductive layer 114A may be formed in a space between the second channel pillar 124 and the uppermost first insulating interlayer 102 as well as the space between the second channel pillars 124.

The conductive layer 114A may be formed by depositing the conductive layer 114A on an entire surface of a structure with the second channel pillar 124, and planarizing the conductive layer 114A until an upper surface of the second channel pillar 124 may be exposed. The gate insulation layer 128 may be partially exposed by the planarization process to expose the upper surface of the second channel pillar 124.

Referring to FIG. 11F, at least one isolation layer 108 extends through the conductive layer 114A. The isolation layer 108 corresponds to the first slit S1 in FIG. 3A and FIG. 3B. The isolation layer 108 includes an insulation layer. For example, the conductive layer 114A may be etched using a hard mask pattern (not shown), to form a trench (not shown) extending through the conductive layer 114A. An insulating material fills the trench to form the isolation layer 108. When the trench is formed, the first insulating interlayer 102 and the memory layer 126 may be partially etched.

Referring to FIG. 11G, the conductive layer 114A may be etched until an upper surface of the conductive layer 114A may be positioned under the upper surface of the second channel pillar 124 to form third conductive patterns 114. The third conductive patterns 114 may be divided by the isolation layer 108. The third conductive patterns 114 may correspond to the drain selection lines DSL1 and DSL2 in FIG. 3A and FIG. 3B.

A second insulating interlayer 104 may be formed on the third conductive patterns 114. The second insulating interlayer 104 may then be planarized. An upper end of the second channel pillar 124, which may be damaged by the etch-back process for forming the third conductive patterns 114, may also be removed by the planarization process. The upper surface of the second channel pillar 124, the upper surface of the second insulating interlayer 104 and the upper surface of the isolation layer 108 may be substantially coplanar with each other by the planarization process. The second insulating interlayer 104 may include an oxide layer.

Referring to FIG. 11H, the sacrificial layer 140 may then be removed by a process that forms the slit structures 130. A conductive material may be formed in a space formed by removing the sacrificial layer 140 to form a first conductive pattern 110 and second conductive patterns 112.

Therefore, a plurality of gate stacks GST divided by the slit structure 130 may be formed.

A third insulating interlayer 106 may be formed on the gate stacks GST and the slit structures 130. The third insulating interlayer 106 may include an oxide layer.

The third insulating interlayer 106 and the second insulating interlayer 104 may be etched using a hard mask pattern as an etch barrier to form a plurality of contact holes 148 configured to expose the upper end of the second channel pillar 124. The upper end of the second channel pillar 124 may be a shape inserted into the contact hole 148.

Impurities may be implanted into the upper end of the second channel pillar 124 exposed through the contact hole 148. The upper end of the second channel pillar 124 may then be thermally treated to form a junction region 124A. The impurities may include n type impurities. The junction region 124A may correspond to a drain of a drain selection transistor.

A plurality of contact plugs 116 may be formed in the contact holes 148. The contact plugs 116 may be configured to connect the second channel pillar 124 with the bit lines formed later.

The upper end of the second channel pillar 124 is disposed within a lower end of the contact plug 116 to increase a contact area between the second channel pillar 124 and the contact plug 116, thereby reducing a contact resistance. Because the upper end of the second channel pillar 124 is disposed within a lower end of the contact plug 116, a part of the isolation layer 108 configured to divide the third conductive patterns 114 is positioned between the contact plugs 116. The upper end of the second channel pillar 124 may be referred to an upper region of the second channel pillar 124. The upper region of the second channel pillar 124 may include an upper surface and upper sidewall extending from the upper surface of the second channel pillar 124.

In an embodiment, referring to FIG. 11H and FIG. 11I, when the contact holes 148 are formed, a drain selection contact hole 148a is formed, through which the third conductive patterns 114 are exposed. A drain selection line contact plug 116a is formed in the drain selection contact hole 148a simultaneously with the contact plug 116 in an embodiment. The third conductive patterns 114 corresponding to the drain selection lines DSL1 and DSL2 or drain selection patterns, which are electrically isolated by the isolation layer 108, receive a drain selection voltage through the drain selection line contact plugs 116a. For example, the contact plugs 116 and the drain selection line contact plugs 116a may include a doped poly silicon material.

Therefore, the memory cell array in FIG. 4 including the gate stacks GST, the slit structures 130, the channel structures CH, and the contact plugs 116 is formed. The slit structures 130 are formed between the gate stacks GST. The channel structures CH extend through the gate stack GST. The contact plugs 116 are formed on or over the gate stacks GST. The contact plugs 116 are electrically connected to the channel structures CH.

The semiconductor memory device may be completed by well-known processes.

According to an embodiment, the second channel pillar 124 may be formed using the mold layer 144 with the mold hole 150. Thus, the first channel pillar 122 and the second channel pillar 124 may be readily aligned with each other so that characteristic deteriorations caused by a misalignment between the first and second channel pillars 122 and 124 may be fundamentally prevented.

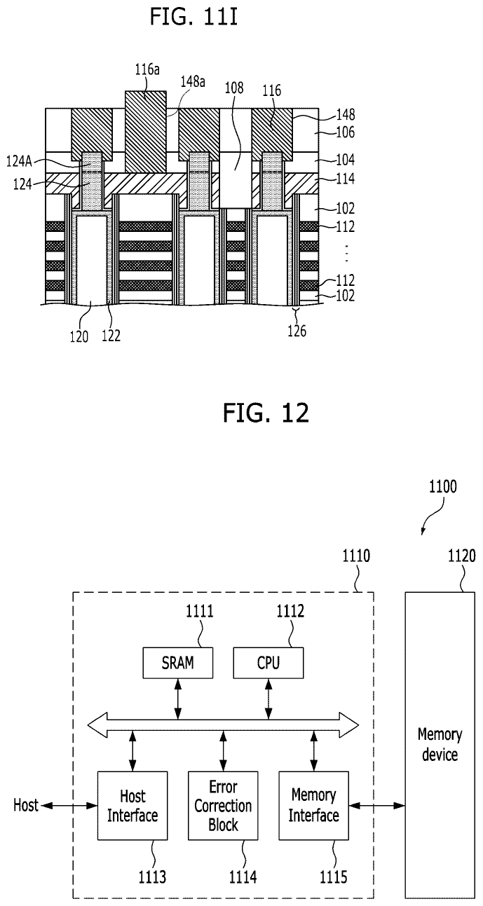

FIG. 12 is a block diagram illustrating a memory system in accordance with an embodiment.

Referring to FIG. 12, a memory system 1100 may include a memory device 1120 and a memory controller 1110.

The memory device 1120 may include gate stacks, channel structures and contact plugs. The gate stacks may include a plurality of stacked conductive patterns spaced apart from each other. The channel structures may penetrate the gate stack. The contact plugs may be formed on the gate stacks. The contact plugs may be overlapped with the channel structures. Each of the channel structures may include a first channel pillar, a memory layer, a second channel pillar and a gate insulation layer. The first channel pillar may penetrate a part of the gate stack. The memory layer may be configured to surround a bottom surface and a side surface of the first channel pillar. The second channel pillar may be extended from an upper surface of the first channel pillar to penetrate remaining gate stacks. The second channel pillar may be connected to the contact plugs. The gate insulation layer may be configured to surround a side surface of the second channel pillar. The memory device 1120 may include the second channel pillar to effectively improve an integration degree of the memory device 1120. Further, a drain selection transistor using the second channel pillar may have improved operational reliability.

The memory device 1120 may include a multi-chip package including a plurality of flash memory chips.

The memory controller 1110 may be configured to control the memory device 1120. The memory controller 1110 may include a static random access memory (SRAM) 1111, a central processing unit (CPU) 1112, a host interface 1113, an error correction block 1114 and a memory interface 1115. The SRAM 1111 may be used for an operation memory of the CPU 1112. The CPU 1112 may be configured to perform control operations including data exchange of the memory controller 1110. The host interface 1113 may include a data exchange protocol of a host coupled to the memory system 1100. The error correction block 1114 may be configured to detect and correct errors in data read from the memory device 1120. The memory interface 1115 may be interfaced with the memory device 1120. The memory controller 1110 may further include a read only memory (ROM) configured to store code data interfaced with the host.

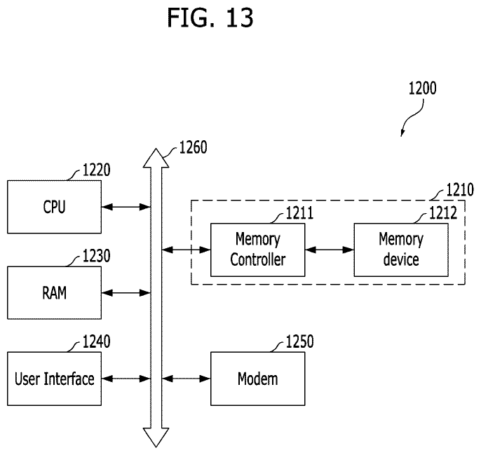

FIG. 13 is a block diagram illustrating a computing system in accordance with an embodiment.

Referring to FIG. 13, a computing system 1200 may include a CPU 1220, a RAM 1230, a user interface 1240, a modem 1250 and a memory system 1210. The computing system 1200 may include a mobile device.

The memory system 1210 may include a memory device 1212 and a memory controller 1211. The memory device 1210 may include gate stacks, channel structures and contact plugs. The gate stacks may include a plurality of stacked conductive patterns spaced apart from each other. The channel structures may penetrate the gate stack. The contact plugs may be formed on the gate stacks. The contact plugs may be overlapped with the channel structures. Each of the channel structures may include a first channel pillar, a memory layer, a second channel pillar and a gate insulation layer. The first channel pillar may penetrate a part of the gate stack. The memory layer may be configured to surround a bottom surface and a side surface of the first channel pillar. The second channel pillar may be extended from an upper surface of the first channel pillar to penetrate remaining gate stacks. The second channel pillar may be connected to the contact plugs. The gate insulation layer may be configured to surround a side surface of the second channel pillar. The memory device 1210 may include the second channel pillar to effectively improve an integration degree of the memory device 1210. Further, a drain selection transistor using the second channel pillar may have improved operational reliability.

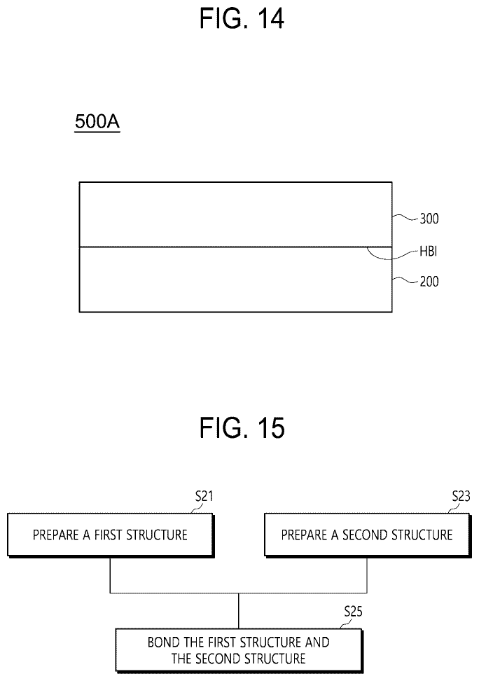

FIG. 14 is a cross-sectional view of a semiconductor memory system in accordance with an embodiment.

Referring to FIG. 14, a semiconductor memory system 500A includes a first structure 200 and a second structure 300. The first structure 200 and the second structure 300 may include different semiconductor device types.

The first structure 200 and the second structure 300 are stacked. The semiconductor memory system 500A includes a bonding interface HBI between the first structure 200 and the second structure 300.

For example, one of the first structure 200 and the second structure 300 includes a semiconductor memory device such as described in FIG. 1 through FIG. 1A through FIG. 11I. The other of the first structure 200 and the second structure 300 includes a different semiconductor device, such as at least one of a peripheral circuit device, a logic circuit device, a high-speed advanced logic processing device, and a high-speed buffer memory device. For example, the first structure 200 may include a first circuit layer (not shown) and the second structure 300 may include a second circuit layer (not shown).

For example, the first structure 200 and the second structure 300 are hybrid-bonded to form the bonding interface HBI between the first structure 200 and the second structure 300. The first structure 200 and the second structure 300 may be bonded without using an intermediate medium such as solder or adhesive. Because the first structure 200 and the second structure 300 are stacked and bonded using the hybrid bonding method, an interface length between the electrical components of the first structure 200 and the second structure 300 may be shortened or decreased, thereby reducing an RC delay through the electrical components.

Each of the first and second circuit layers includes electrical components (not shown) having differing functions. In an embodiment, the first and second circuit layers of the structures 200 and 300 is fabricated through a front-end-of-line (FEOL) process.

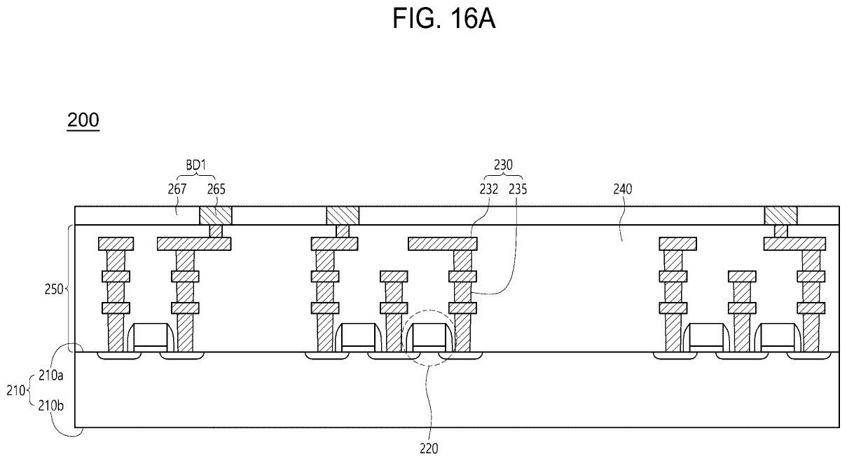

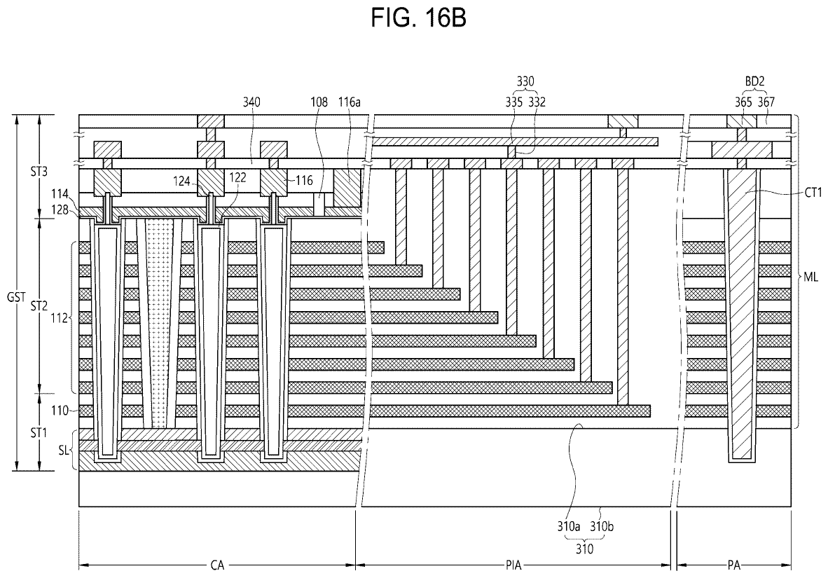

FIG. 15 is a flowchart illustrating a method of manufacturing a semiconductor memory system in accordance with an embodiment. The processes of the flowchart may be performed in a different order and may include fewer or additional processes than described and shown in FIG. 15. FIG. 16A through FIG. 16C are cross-sectional views of a semiconductor memory device manufactured utilizing a method of manufacturing a semiconductor memory system in accordance with an embodiment.

Referring to FIG. 15, the method of manufacturing the semiconductor memory system includes preparing S21 the first structure 200 and preparing S23 the second structure 300. The order of preparing the first structure and the second structure may vary. The processes of the flowchart may be performed in a different order and may include fewer or additional processes than described and shown in FIG. 15.

Referring to FIG. 16A, the first structure 200 includes a first substrate 210 and a first circuit layer 250. The first substrate 210 includes a front or top surface 210a and a back or bottom surface 210b. For example, a “surface” may also be referred to as a “side”. The first substrate 210 includes a semiconductor wafer. Alternatively, the first substrate 210 includes a semiconductor die or a semiconductor chip that include parts of the semiconductor wafer. The substrate 210 may include conductive dopants. A device isolation layer (not shown) may be formed in the front surface 210a of the first substrate 210 to electrically isolate electrical components formed on the first surface 210a of the first substrate 210. For example, active regions (not shown) of the first substrate 210 may be delineated within the device isolation layer. The electrical components are integrated in the active regions.

The first circuit layer 250 is disposed on or over the front surface 210a of the first substrate 210. The first circuit layer 250 includes a plurality of transistors 220, a plurality of interconnection structures 230, and at least one interlayer insulating layer 240. Alternatively, the first circuit layer 250 includes at least one passive element (not shown) such as a capacitor, a resistor, or an inductor. The plurality of transistors 220 are integrated in the active regions of the first substrate 210. For example, the electrical components of the first circuit layer 250 include at least one of the transistors 220, the interconnection structures 230, and the passive elements.

The plurality of first interconnection structures 230 include a plurality of horizontal wirings or electrical conductors 232 and a plurality of vertical wirings or electrical conductors 235. The interconnection structures 230 connect the transistors 220 and the passive elements. For example, the vertical wirings 235 electrically connect adjacent horizontal wirings 232 to transmit signals. The horizontal wirings 232 extend in a direction parallel to the front surface 210a or the back surface 210b of the first substrate 210. The vertical wirings 235 extend in a direction perpendicular to the front surface 210a or back surface 210b of the first substrate 210. The vertical wirings 235 are referred to as plugs or contacts. The interconnection structures 230 may be formed using a conductive semiconductor layer, a silicide layer, or a metal layer.

The interlayer insulating layer 240 is disposed between the transistors 220 and the horizontal wirings 232, between consecutive horizontal wirings 232, and between consecutive vertical wirings 235. The interlayer insulating layer 240 electrically isolates the horizontal wirings 232 and vertical wirings 235 that transmit different signals. The interlayer insulating layer 240 may include various insulating materials such as silicon oxide, silicon nitride, silicon oxynitride, or high-k dielectrics.

The transistors 220 and the passive elements re electrically coupled by the interconnection structures 230 to form the first circuit layer 250 including a peripheral circuit device and a logic circuit device. For example, the peripheral circuit device and the logic circuit device may include at least one of a page buffer, a decoding circuit, a sense amplifier, a voltage generator, a voltage regulator, a read/write circuit, a timing control circuit, and an input/output buffer, but is not limited to this example. For example, the first circuit layer 250 may include a high-speed advanced logic device and a high-speed buffer memory device. In an embodiment, at least one of a DRAM (Dynamic Random Access Memory), a SRAM (Static RAM), a resistive memory, and a neuromorphic memory may be integrated as the first circuit layer 250 in addition to the peripheral circuit device and the logic circuit device. For example, the first circuit layer 250 may include a memory function, and the first circuit layer 250 may include a memory element (not shown). The memory element may include a ferroelectric material, a magneto-resistive material, a phase-change material, or a two-dimensional material as a storage material.

For example, the plurality of transistors 220 may have different threshold voltages to perform different characteristics.

The first structure 200 may include a first bonding layer BD1. The first bonding layer BD1 is disposed on or over the first circuit layer 250. The first bonding layer BD1 includes a plurality of first bonding pads 265 and a first bonding insulating layer 267. The bonding pads 265 are directly or indirectly connected to the interconnection structures 230. The bonding insulating layer 267 electrically isolates the bonding pads 265 from each other. For example, the bonding pads 265 may include Copper (Cu), tungsten (W), Cobalt (Co), or other metals. The bonding insulating layer 267 may include silicon oxide, silicon nitride, or silicon oxynitride.

Referring to FIG. 16B, the second structure 300 may include a second substrate 310 and a memory device layer ML as the second circuit layer. The second substrate 310 includes a front or top surface 310a and a back or bottom surface 310b. The second substrate 310 includes, for example, a semiconductor substrate, although the second substrate 310 is not limited to this example.

The memory device layer ML is disposed over the front surface 310a of the second substrate 310. The memory device layer ML includes a cell array region CA, a pickup region PIA, and a peri-contact region, or peripherical contact region, PA. A gate stack GST of the memory device illustrated in FIG. 3 to FIG. 7 is integrated in the cell array region CA. The gate stack GST includes at least one channel structure CH including the first channel pillar 122 and the second channel pillar 124. The first channel pillar 122 corresponds to a channel of the memory cell string CS of FIG. 2, and the second channel pillar 124 corresponds to a channel of a drain select transistor DST of FIG. 2. The channel structure CH, the third conductive patterns 114 corresponding to the drain selection lines, the isolation layer 108, the contact plug 148 and the drain selection line contact plug 148a may be fabricated according the manufacturing method described with respect to FIG. 10A to FIG. 10K or the manufacturing method described with respect to FIG. 11A to FIG. 11I.

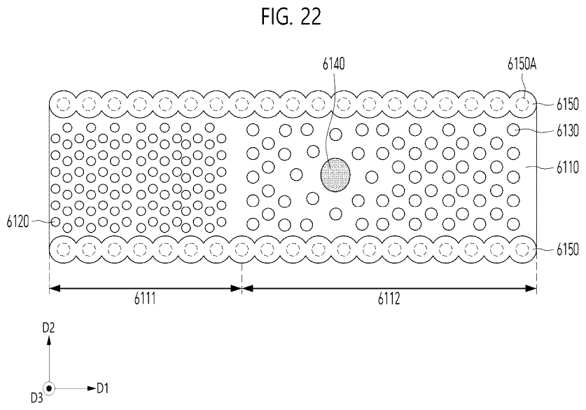

The conductive patterns 110, 112, and 114 of the gate stack GST extend into the pickup region PIA and the peri-contact region PA. The conductive patterns 110, 112, and 114 located in the pickup region PIA may be processed to formed a stepped shape that contacts external signal terminals. Such step-shaped processing of the conductive patterns 110, 112, and 114 in the pickup region PIA may be referred to as slimming. The slimming process in the pickup region PIA may vary depending on the quantity of stacked conductive patterns 110, 112, and 114. The conductive patterns 110, 112, and 114 may be electrically connected to receive signals not only as a result of the slimming process but also by a Stairless Sliming Contact (SSC) structure. In an embodiment, a selection line, a plurality of word lines, and the drain selection patterns in the pickup region have progressively different lengths in the first direction D1 and the second direction D2, including gradually differing lengths from line to line. The SSC structure is described with respect to FIG. 22. The peri-contact region PA includes at least one peri-contact CT1 formed in the gate stack GST. For example, the peri-contact CT1 connects between the peripheral circuit of the first structure 200 and an external terminal (not shown).

The second structure 300 includes a plurality of second interconnection structures 330, at least one interlayer insulating layer 340, and a second bonding layer BD2.

The plurality of second interconnection structures 330 is disposed on or over the memory device layer ML. The plurality of second interconnection structures 330 includes a plurality of vertical wirings 332 and a plurality of horizontal wirings 335 that are directly or indirectly connected to electrical components constituting the memory device layer ML. The material(s) of the second interconnection structures 330 may be similar to the material(s) of the first interconnection structures 230.

The interlayer insulating layer 340 is disposed between the electrical components of the memory device layer ML, between consecutive vertical wirings 332, and between consecutive horizontal wirings 335. In an embodiment, the second interconnection structures 330 and the interlayer insulating layer 340 may be included in the memory device layer ML.

The second bonding layer BD2 is disposed on or over the memory device layer ML. The second bonding layer BD2 includes a plurality of second bonding pads 365 and a second bonding insulating layer 367. The plurality of second bonding pads 365 are directly or indirectly connected to the plurality of second interconnection structures 330. The second bonding insulating layer 367 electrically insulates the second bonding pads 365 from each another. For example, the second bonding pads 365 may include Copper (Cu), tungsten (W), Cobalt (Co), or other metals. The second bonding insulating layer 367 may include silicon oxide, silicon nitride, or silicon oxynitride.

Referring to FIG. 15 and FIG. 16C, the first structure 200 is hybrid-bonded S25 to the second structure 300. In an embodiment, the second structure 300 is flipped or reversed in the vertical direction with respect to the FIG. 16C such that the second bonding layer BD2 of the second structure 300 faces the first bonding layer BD1 of the first structure 200. When the second structure 300 is flipped, the back surface 310b of the second substrate 310 of the second structure 300 is exposed to a processing space (not shown). In an embodiment, the first bonding layer BD1 is bonded to the second bonding layer BD2 using a hybrid bonding method, thereby forming a stacked-type semiconductor memory system 500A. For example, the processing space includes an inner space of a process chamber that performs processes on a semiconductor device. The electrical components of the first structure 200 and the electrical components of the second structure 300 transfer electrical signals through the bonding pads 265 and 365 that are hybrid bonded together.

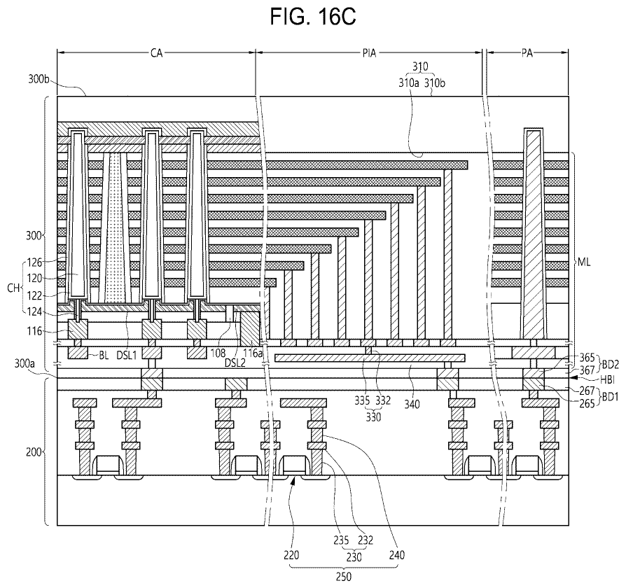

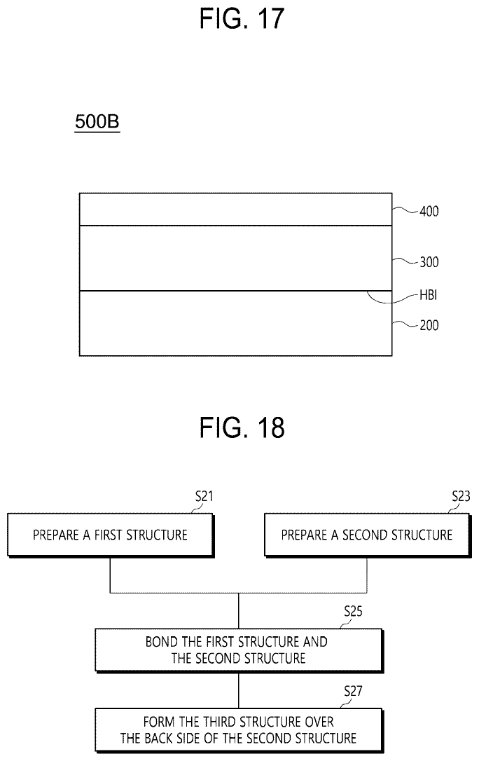

FIG. 17 is a cross-sectional view of a semiconductor memory system in accordance with an embodiment.

Referring to FIG. 17, a semiconductor memory system 500B includes a first structure 200, a second structure 300, and a third structure 400. The first structure 200 and the second structure 300 may be similar to configurations described with respect to FIG. 16A to FIG. 16C.

The third structure 400 is formed on or over a back or top surface of the second structure 300. For example, the third structure 400 includes a plurality of third interconnection structures and an interlayer insulating layer. For example, the third interconnection structures are electrically connected to the electrical components of the memory device layer ML of the second structure 300 as shown in FIG. 16B. The interlayer insulating layer of the third structure 400 insulates between the third interconnection structures. For example, the third interconnection structures are disposed over the back or top surface of the second structure 300 at various heights from the back surface of the second structure 300.

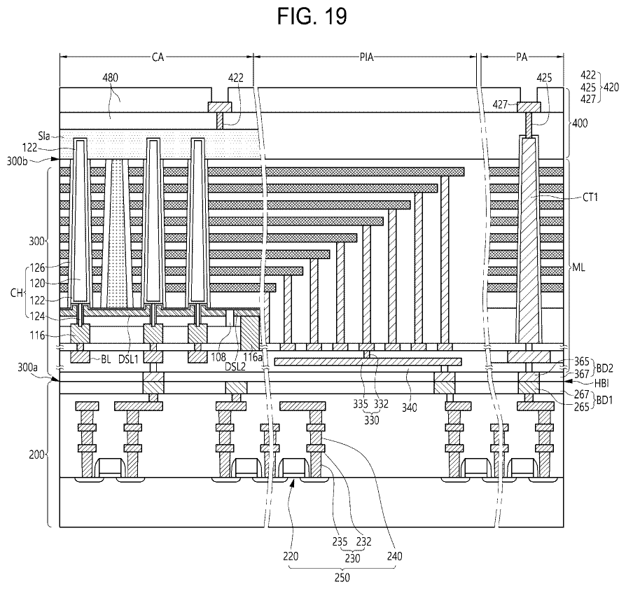

FIG. 18 is a flowchart of a method of manufacturing a semiconductor memory system in accordance with an embodiment. The processes of the flowchart may be performed in a different order and may include fewer or additional processes than described and shown in FIG. 18. FIG. 19 is a cross-sectional view of a semiconductor memory device manufactured utilizing a method of manufacturing a semiconductor memory system in accordance with an embodiment.

Referring to FIG. 15, FIG. 18, and FIG. 19, after the first structure 200 is bonded S25 to the second structure 300, the third structure 400 is formed S27 on or over the back or top surface of the second structure 300.

The first structure 200 may be substantially similar to the structure described with respect to FIG. 16A.

The second structure 300 includes a memory device layer ML, a second interconnection structure 330, an interlayer insulating layer 340, and a second bonding layer BD2. For example, the second structure 300 includes a front or lower surface 300a and a back or upper surface 300b similar to FIG. 16B. In an embodiment, a bonding interface HBI of the second bonding layer BD2 corresponds to the front or lower surface 300a of the second structure 300. A lower region of the memory device layer ML corresponds to the back or upper surface 300b of the second structure 300.

The memory device layer ML may include a cell array region CA, a pick up region PIA, and a peri-contact region PA which have a gate stack GST, as described with respect to FIG. 1 through FIG. 16B. The gate stack GST includes conductive patterns 110, 112, and 114 alternately stacked with interlayer insulating layers 102 and 104. The conductive patterns 110, 112, and 114 may be referred to as gate lines. For example, the gate lines include a source selection line SSL, a plurality of word lines WL1 to WLn, and a plurality of drain selection lines DSL1 and DSL2. For example, the source selection line SSL may be closer to the back surface 300b of the second structure 300, and the drain selection lines DSL1 and DSL2 may be closer to the front surface 300a of the second structure 300. The second structure 300 does not include a source line in an embodiment.

A plurality of channel structures CH are disposed within the cell array region CA. The plurality of channel structures CH are formed through the gate stack GST, and bottom ends of the plurality of channel structures CH protrude by a distance from the back surface 300b of the second structure 300. A first channel layer 122A of a first channel pillar 122 that is positioned at a protruding end of the channel structure CH is exposed. The channel structures CH includes the first channel pillar 122 and a second channel pillar 124 as shown in FIG. 6.

The gate structure GST includes an isolation layer 108 that forms electrically isolated drain selection lines or drain selection patterns DSL1 and DSL2.

The gate stack GST in the cell array region CA includes contact plugs 116 that each contact a corresponding second channel pillar 124. For example, the contact plugs 116 are electrically connected to bit lines BL.

The gate stack GST in the cell array region CA includes drain selection line contact plugs 116a. The drain selection line contact plugs 116a that contact separated drain selection lines DSL1 and DSL2. Through the drain selection line contact plugs 116a, the drain selection lines DSL1 and DSL2 receive a drain select signal. The contact plugs 116 and the drain selection line-contact plugs 116A may be formed using the same process as described in FIG. 10A to FIG. 10K and FIG. 11A to FIG. 11 through FIG. 11I. In an embodiment, the contact plugs 116 and the drain selection line contact plugs 116A located at the same level may have different sizes.

The second interconnection structure 330 is formed over the gate stacks GST that are formed above the cell array region CA, the pickup region PIA, and the peri-contact region PA. The second interconnection structure 330 includes a plurality of vertical wirings 332 and a plurality of horizontal wirings 335. Electrical components constituting the gate stack GST, such as the gate lines 110, 112, and 114, the bit lines BL, and the peri-contacts CT1, are electrically connected to the second interconnection structure 330. The interlayer insulating layer 340 electrically isolates the second interconnection structure 330 that receives different voltages or signals. The second bonding layer BD2 is disposed on top of the uppermost interlayer insulating layer. The second bonding layer BD2 includes a plurality of second bonding pads 365 and a second bonding insulating layer 367. Although not shown in detail in the drawings, the plurality of second bonding pads 365 are directly or indirectly connected to the second interconnection structure 330. Accordingly, the plurality of second bonding pads 365 are electrically connected to the electrical components of the second structure 300.

The third structure 400 includes a back side source line Sla, a third interconnection structure 420, and at least one interlayer insulating layer 480.

The back side source line Sla is formed on the back or top surface 300b of the second structure 300. The back side source line Sla contacts the channel layers 122 of the channel structures CH that protrude through the back surface 300b of the second structure 300.

The third interconnection structures 420 includes at least one conductive layer that is directly or indirectly connected to the electrical components of the second structure 300. For example, the third interconnection structures 420 include a back side source contact 422 connected to the back side source line Sla, an external local contact 425 connected to the peri-contact CT1, and a contact pad 427. Although not illustrated in the drawings, the third interconnection structure 420 may include a redistribution layer. The back side source contact 422, the external local contact 425, and the contact pad 427 may be positioned at different heights or planes or may be located at the same height. The interlayer insulating layer 480 is formed over the second structure 300 to electrically insulate the third interconnection structures 420 from each other to facilitate receipt of different voltages.

In an embodiment, the third structure 400 is formed by treating the back surface of the second structure 300. For example, the third structure 400 may be fabricated through a back-end-of-line (BEOL) process. Accordingly, the bonding interface HBI, such as the interface between the first structure 200 and the second structure 300, may not be formed between the second structure 300 and the third structure 400.

For example, the third structure 400 may be formed in the following manner. The back surface 310b of the second substrate 310 of FIG. 16B is thinned to expose the channel layers 122 at the bottom regions or ends of the channel structures CH. The thinning of the second substrate 310 may be performed using chemical mechanical polishing (CMP), back-grinding, dry etching, or wet etching.

The back side source layer Sla is formed on the back surface 300b of the second substrate 300 corresponding to the cell array region CA. The back side source line Sla contacts the exposed channel layers 122A of the channel structures CH. The interlayer insulating layer 480 is disposed over the back side source layer Sla and the back surface 300b of the second structure 300. For example, a back side source contact 422, a local contact 425, at least one external pad 427, and the redistribution layer are formed in/on the interlayer insulating layer 480. The back side source contact 422 is electrically coupled to the back side source layer Sla. The local contact 425 is electrically coupled to the peripheral contact CT1 and other electrical components. The external pad 427 is electrically coupled to the back side source contact 422 or the local contact 425.

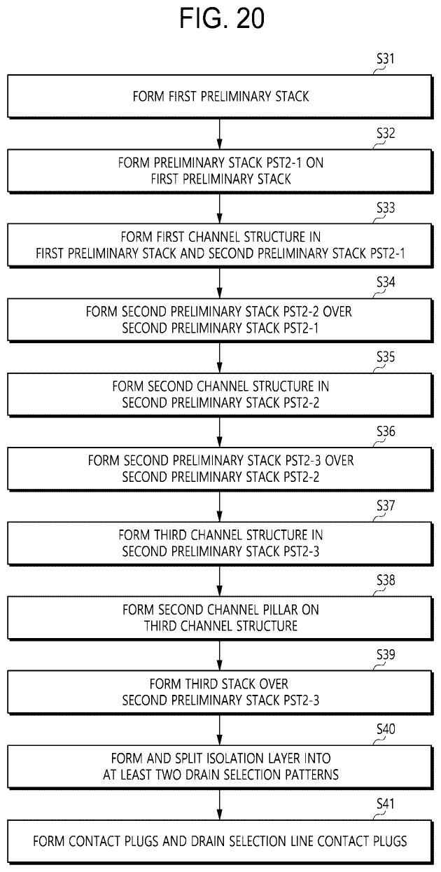

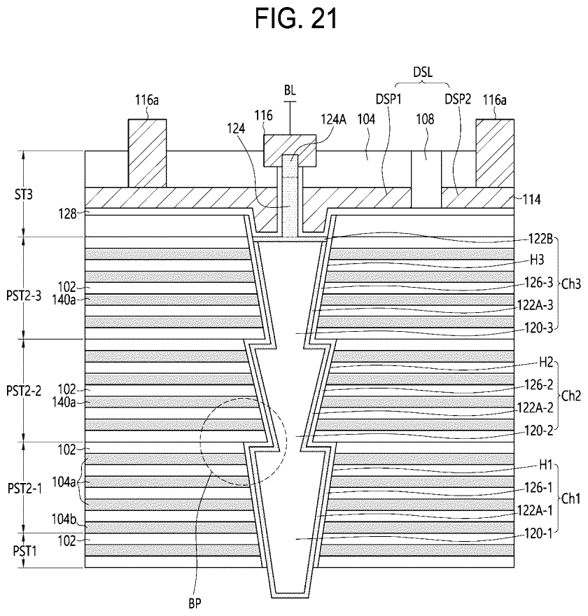

FIG. 20 is a flowchart of a method of manufacturing a second structure including a channel pillar in accordance with an embodiment. The processes of the flowchart may be performed in a different order and may include fewer or additional processes than described and shown in FIG. 20. FIG. 21 is a cross-sectional view of a second structure including a channel pillar in accordance with an embodiment.

Referring to FIG. 20 and FIG. 21, a first preliminary stack PST1 is formed S31 on a second substrate (not shown) of a second structure 300A. For example, the second substrate includes a source layer SL. The source layer SL (not shown) includes source layers SL1, SL2, and SL3 having a similar structure as described with respect to FIG. 4. In an example, the second substrate does not include a source layer such as shown in FIG. 19.

As described, the first preliminary stack PST1 is formed by alternately and repeatedly stacking at least one sacrificial layer 140b with at least one insulating interlayer 102. The sacrificial layer 140b is subsequently replaced with the source selection line SSL or first conductive patterns 110.

A second preliminary stack PST2-1 is formed S32 on or over the first preliminary stack PST1. The second preliminary stack PST2-1 is formed by alternately and repeatedly stacking the sacrificial layers 140a with the insulating interlayers 102. The sacrificial layers 140a of the second preliminary stack PST2-1 are replaced with the word lines WL or second conductive patterns 112 as described with respect to FIG. 4.

A first channel structure Ch1 is formed S33 within the first preliminary stack PST1 and the second preliminary stack PST2-1. The first channel structure Ch1 includes a first memory layer 126-1, a first channel layer 122A-1, and a first core pillar 120-1.

A first channel hole H1, in which the first channel structure Ch1 is formed, is formed through the second preliminary stack PST2-1 and the first preliminary stack PST1. Because of the combined height of the two stacks PST1 and PST2-1, the first channel hole H1 may have a high aspect ratio. Accordingly, the diameter of the first channel hole H1 gradually decreases or tapers toward a lower end or bottom region toward the source layer SL. As a result, a shape of the first channel structure Ch1 formed in the first channel hole H1 depends on a shape of the first channel hole H1.

The sacrificial layers 140a for the word line, the sacrificial layers 140b for the source selection line, the insulating layers 102, and the third source layer SL3 to the first source layer SL1 are exposed through the first channel hole H1. The first source layer SL1 (not shown) is exposed through a bottom of the first channel hole H1. For example, the first channel hole H1 extends through the second source layer SL2 and the third source layer SL3, but not the first source layer SL1. In an example, the sacrificial layer 140a and 140b, the insulating interlayers 102, and the second substrate 310 are exposed through the first channel hole H1.

The first memory layer 126-1 is formed along the sidewall of the stacks PST1 and PST2-1 adjacent to the first channel hole H1 and a surface of the source layer SL adjacent to the first channel hole H1. The first channel layer 122A-1 is formed along the first memory layer 126-1 and the third source layer SL3. The first core pillar 120-1 fills in the first channel layer 122A-1, thereby forming the first channel structure Ch1. For example, an upper surface of the first channel structure Ch1 is substantially on the same plane as an upper surface of the second preliminary stack PST2-1.

A second preliminary stack PST2-2 is formed S34 over the second preliminary stack PST2-1 including the first channel structure Ch1. The second preliminary stack PST2-2 is formed by alternately and repeatedly stacking the sacrificial layers 140a with the insulating interlayers 102. The sacrificial layers 140a of the second preliminary stack PST2-2 are replaced with the word lines 112 as described with reference to FIG. 4.

A second channel structure Ch2 is formed S35 in the second preliminary stack PST2-2. The second channel structure Ch2 includes a second memory layer 126-2, a first channel layer 122A-2, and a second core pillar 120-2.

A second channel hole H2, in which the second channel structure Ch2 is formed, is formed through the second preliminary stack PST2-2. For example, the second channel hole H2 is formed, through which the upper surface of the first channel structure Ch1 is exposed. The sacrificial layers 140a and the insulating interlayers 102 are exposed through the second channel hole H2. Due to the height of the second preliminary stack PST2-2, the second channel hole H2 may have a high aspect ratio. Accordingly, the diameter of the second channel hole H2 gradually decreases or tapers toward the first channel structure Ch1. A shape of the second channel structure Ch2 depends on a shape of the second channel hole H2. For example, a diameter of a bottom region the second channel hole H2 is smaller than a diameter of an upper region of the first channel structure Ch1. For example, the bottom region or end of the second channel hole H2 is open to the upper region or end of the first channel structure Ch1.

The second memory layer 126-2 is formed along a sidewall of the second preliminary stack PST2-2 adjacent to the second channel hole H2 and is connected to the first memory layer 126-1. The first channel layer 122A-2 is formed along the second memory layer 126-2 and is connected to the first channel layer 122A-1. The second core pillar 120-2 fills in the first channel layer 122A-2 and is connected to the first core pillar 120-1. Thus, the second channel structure Ch2 is formed in the second channel hole H2. An upper surface of the second channel structure Ch2 is substantially on the same plane as an upper surface of the second preliminary stack PST2-2.

A second preliminary stack PST2-3 is formed S36 over the second preliminary stack PST2-2 including the second channel structure Ch2. The second preliminary stack PST2-3 is formed by alternately and repeatedly stacking the sacrificial layers 140a with the insulating interlayers 102. The sacrificial layers 140a of the second preliminary stack PST2-3 are replaced with the word lines 112 illustrated in FIG. 4.

A third channel structure Ch3 is formed S37 in the second preliminary stack PST2-3. The third channel structure Ch3 includes a third memory layer 126-3, a first channel layer 122A-3, a third core pillar 120-3, and a second channel layer 122B.

A third channel hole H3, in which the third channel structure Ch3 is formed, is formed in the second preliminary stack PST2-3. For example, the third channel hole H3 is formed, through which the upper surface of the second channel structure Ch2 is exposed. Due to the height of the second preliminary stack PST2-3, the third channel hole H3 may have a high aspect ratio. Accordingly, a diameter of the third channel hole H3 gradually decreases or tapers toward the second channel structure Ch2. A shape of the third channel structure Ch3 depends on a shape of the third channel hole H3. For example, a diameter of a bottom region of the third channel hole H3 is smaller than a diameter of an upper region of the second channel structure Ch2. For example, the bottom region or end the third channel hole H3 is open to the upper region or end of the second channel structure Ch2.

The third memory layer 126-3 is formed along a sidewall of the stack PST2-3 adjacent to the third channel hole H3 and is connected to the second memory layer 126-2. The first channel layer 122A-3 is formed along the third memory layer 126-3 and is connected to the first channel layer 122A-2. A gap-fill material fills the first channel layer 122A-3. The gap-fill material and the first channel layer 122A-3 may be recessed below an upper surface of the second preliminary stack PST2-3, thereby forming the third core pillar 120-3. The second channel layer 122B is formed to cover an upper surface of the first channel layer 122A-3 and an upper surface of the third core pillar 120-3, thereby forming the third channel structure Ch3.

In an embodiment, an upper surface of the second channel layer 122B is at a lower level than the upper surface of the second preliminary stack PST2-3. An upper surface of the third memory layer 126-3 is substantially on the same plane as the upper surface of the second preliminary stack PST2-3. As a result, a step difference occurs between the upper surface of the third memory layer 126-3 and the upper surface of the first channel layer 122A-3.

The first channel layers 122A-1, 122A-2, and 122A-3 extend continuously in a primarily vertical direction along the sidewalls of the preliminary stacks PST1, PST2-1, PST2-2, PST2-3 adjacent to the first channel hole H1, the second channel hole H2, and the third channel hole H3. Accordingly, a signal transmission path is established among the second channel layer 122B and the first channel layers 122A-1 to 122A-3. Because each of the first channel hole H1 to the third channel hole H3 has a decreasing or tapering diameter toward the source layer SL or bottom of the device, a bending region BP occurs at junctions or connections between consecutive first channel layers 122A-1 to 122A-3, such that the first channel layers 122A-1 to 122A-3 have angled sections in the bending regions BP.

A second channel pillar 124 is formed S38 on the third channel structure Ch3. A width of the second channel pillar 124 is narrower than a width of the second channel layer 122B of the third channel structure Ch3. The second channel pillar 124 is formed in a cylindrical or curved shape. The second channel pillar 124 is disposed about a center of the third channel structure Ch3.

A third stack ST3 is formed S39 over the second preliminary stack PST2-3. For example, the third stack ST3 includes a gate insulating layer 128 formed along the upper surface of the second preliminary stack PST2-3 and along a sidewall of the second channel pillar 124. A drain selection line DSL is formed on the gate insulating layer 128. For example, the drain selection line DSL extends in a horizontal direction parallel to the source line SL. The drain selection line DSL may include a metal. The gate insulating layer 128 electrically insulates the drain selection line DSL from the third memory layer 126-3, the second channel layer 122B, and the second channel pillar 124. The third stack ST3 further includes a second interlayer insulating layer 104 formed on the drain selection line DSL.

The third stack ST3 includes an isolation layer 108 that splits S40 the drain selection line DSL into at least two drain selection patterns DSP1 and DSP2. The drain selection patterns DSP1 and DSP2 are separated from each other by the isolation layer 108. The drain selection patterns DSP1 and DSP2 are located in one plane, and the drain selection patterns DSP1 and DSP2 individually receive electrical signals.

Contact plugs 116, that contact the second channel pillars 124, and drain selection line contact plugs, 116a that contact the drain selection patterns DSP1 and DSP2, are formed S41.

Although not illustrated in FIG. 20 and FIG. 21, before or after forming the third stack ST3, the sacrificial layers 140a and 140b within the second preliminary stacks PST2-3 to PST2-1 and the first preliminary stack PST1 are replaced with conductive layers to form the word lines and the source selection line. The conductive layers may include, for example, tungsten or molybdenum.

FIG. 22 is a plan view illustrating a structure of a semiconductor memory device in accordance with an embodiment.

Referring to FIG. 22, the semiconductor memory device includes a gate structure 6110, such as GST in FIG. 2 and FIG. 4, a plurality of channel structures 6120, such as CH in FIG. 4 to FIG. 7, a plurality of support structures 6130, a plurality contact plugs 6140, and a plurality of slit structures 6150.

For example, the slit structures 6150 extend in a first direction D1. The gate structure 6110 is located between consecutive slit structures 6150. The slit structures 6150 may include at least one of an insulating material, a semiconductor material, and a conductive material.

The gate structure 6110 includes a plurality of gate lines alternately stacked with a plurality of insulating interlayers. For example, the plurality of gate lines include a source selection line SSL, a plurality of word lines WL1 to WLn, and at least two drain selection lines DSL1 and DSL2, such as shown in FIG. 2, FIG. 3A, and FIG. 3B.

The contact plugs 6140 are signal transmission media electrically connected to the word lines and the source selection line.

The gate structure 6110 includes a cell array region 6111, such as CA in FIG. 19, a pickup region 6112, such as PIA in FIG. 19, and a peri-contact region (not shown), such as PA shown in FIG. 19. The channel structures CH are located in the cell array region 6111 of the gate structure 6110. The channel structures 6120 vertically extend in a third direction D3 through the gate structure 6110, and memory cells are stacked along the channel structures 6120. The channel structure 6120 correspond to the channel structures CH described with respect to FIG. 1 to FIG. 21.

The support structures 6130 and the contact plugs 6140 are located in the pickup region 6112 of the gate structure 6110. The support structures 6130 vertically extend through the gate structure 6110. The support structures 6130 may include at least one of an insulating material, a semiconductor material, and a conductive material.

One of the contact plugs 6140 is electrically connected to a selected gate line of the gate lines. For example, the gate lines of the gate structure 6110 do not have a stepped structure. Instead of the gate lines having the stepped structure, the gate lines receive a gate signal via the contact plugs 6140 that have different heights. The contact plugs 6140 may be also referred to as a stairless slim contact (SSC). The contact plugs 6140 extend through the gate structure 6110 to electrically connect to the gate lines.

The fabrication processes of the channel structures 6120, the support structures 6130, the contact plugs 6140, and the slit structures 6150 may be performed simultaneously. For example, a plurality of holes (not shown) are simultaneously formed in a preliminary gate structure including sacrificial layers, and the channel structures 6120, the support structures 6130, the contact plugs 6140, and the slit structures 6150 are formed in the holes.

The holes are opened to form structures, such as the channel structures CH, the support structures 6130, the contact plugs 6140, and the slit structures 6150. For example, the slit structures 6150 may be formed by filling a plurality of holes 6150A that are continuously arranged in the first direction D1. For example, the slit structures 6150 may be formed by filling interconnected neighboring holes that are constructed by expanding or increasing the diameters of the holes 6150A, thereby forming a substantially linear structure in a planar view. For example, the slit structure 6150 may correspond to the second slits S2 of FIG. 3A or 3B or slits 130 of FIG. 4. Sidewalls of the slit structures 6150 have an uneven profile or shape in a planar view in this example.

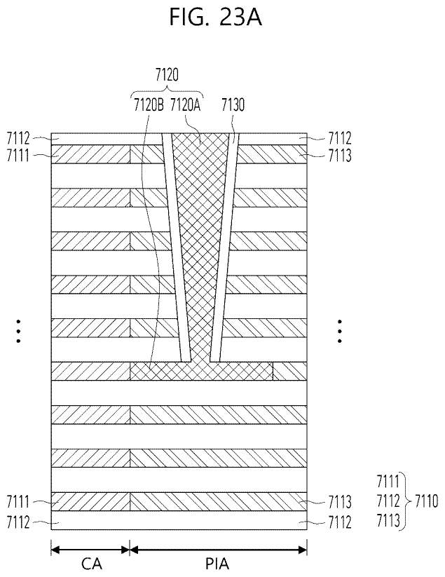

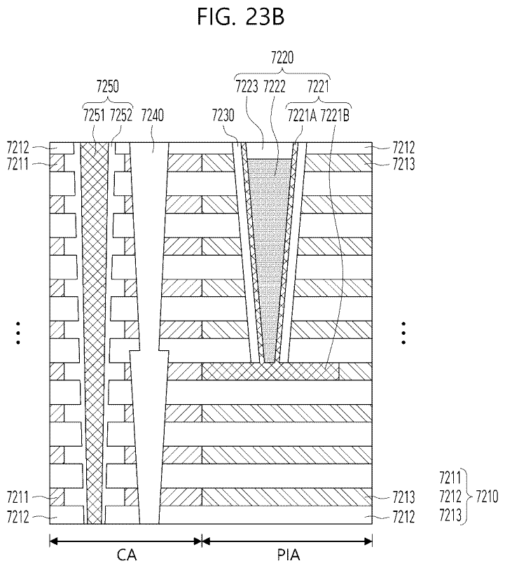

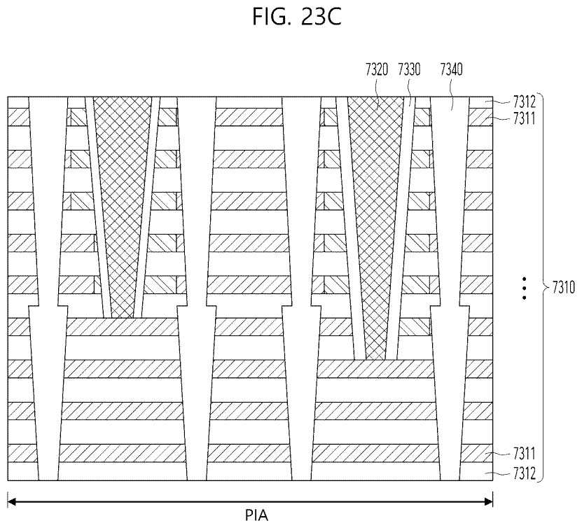

FIG. 23A is a cross-sectional view illustrating a semiconductor memory device in accordance with an embodiment.

Referring to FIG. 23A, the semiconductor memory device includes a gate structure 7110, a plurality of contact plugs 7120, and insulating spacers 7130.

The gate structure 7110 includes a plurality of gate lines 7111, insulating interlayers 7112, and dielectric layers 7113. For example, the gate lines 7111 are alternately stacked with the insulating interlayers 7112 in a cell array region CA. The dielectric layers 7113 are alternately stacked with the insulating interlayers 7112 in a pickup region PIA. The dielectrics layers 7113 of the pickup region PIA are aligned with the gate lines 7111 of the cell array region CA. The gate lines 7111 correspond to the conductive patterns 110 and 114, for example, as shown in FIG. 4 through FIG. 7. The dielectric layers 7113 correspond to the sacrificial layers 114.

Each of the contact plugs 7120 includes a pillar 7120A and a contact 7120B protruding from the pillar 7120A. The pillar 7120A extends vertically through the insulating layers 7112 and the dielectric layers 7113. The contact 7120B is located at a level corresponding to a dielectric layer 7113 and extends in a horizontal direction to electrically connect to a gate line 7111. The insulating spacer 7130 surrounds the pillar 7120A.

In an embodiment, the semiconductor memory device includes a plurality of contact plugs extending to different depths, each contact plug connected to a different gate lines 7111.

The semiconductor memory semiconductor device may be fabricated using a replacement process. For example, a preliminary stack is formed including sacrificial layers, such as 114 of FIG. 21, alternately stacked with the insulating interlayers 7112. The sacrificial layers of the preliminary stack are replaced with the gate lines 7111 to form the gate structure 7110. In this example, some of the sacrificial layers remain in regions of the stacked structure, for example, in the pickup region PIA. The dielectric layers 7113 of the gate structure 7110 are the remaining sacrificial layers.

The contact holes extending through the insulating layers 7112 and the dielectric layers 7113 are formed. The insulating spacer 7130 is formed along an inner wall of the gate structure 7110 adjacent to each contact hole. The exposed dielectric layer 7113 at a bottom surface of the contact hole may be etched to horizontally expand a lower end of the contact hole and expose the gate line 7111. The contact plug 7120 is formed in the contact hole.

FIG. 23B is a cross-sectional view illustrating a semiconductor memory device in accordance with an embodiment.

Referring to FIG. 23B, the semiconductor device includes a gate structure 7210, a plurality of contact plugs 7220, insulating spacers 7230, a plurality of support structures 7240, and a slit structure 7250.

The gate structure 7210 includes a plurality of gate lines 7211, insulating interlayers 7212, and dielectric layers 7213. The gate lines 7211 are alternately stacked with the insulating interlayers 7212 in the cell array region CA, and the insulating interlayers 7212 may extend between the stacked dielectric layers 7213 in the pickup region PIA.

The support structures 7240 extend through the alternately stacked gate lines 7211 and insulating interlayers 7212. The support structures 7240 may include at least one of an insulating material, a semiconductor material, and a conductive material.

The slit structure 7250 may be formed within a slit used as a path for a replacement process. The slit structure 7250 may extend between adjacent gate structures 7210. For example, the slit structure 7250 includes a conductive layer 7251 and an insulating spacer 7252 surrounding sidewalls of the conductive layer 7251. The insulating spacer 7252 includes protrusions extending toward the gate lines 7211.

The contact plug 7220 includes a conductive layer 7221, a gap-fill insulating layer 7222, and a contact pad 7223. For example, the conductive layer 7221 may include a barrier metal such as TiN. The gap-fill insulating layer 7222 extends vertically through the dielectric layers 7213 and the insulating interlayers 7212. The contact pad 7223 is located on the gap-fill insulating layer 7222 and may include a metal such as tungsten (W).

The conductive layer 7221 includes a pillar 7221A and a contact 7221B. The pillar 7221A surrounds sidewalls of the gap-fill insulating layer 7222 and the contact pad 7223. The contact 7221B extends from a bottom surface of the gap-fill insulating layer 7222 and extends in a horizontal direction to electrically connect to a gate line 7211. The insulating spacer 7230 surrounds the pillar 7221A.

The semiconductor memory device includes a plurality of contact plugs 7220. Each of the plurality of contact plugs 7220 extends to different depth and is connected to a different gate line 7211.

The semiconductor memory device may be fabricated using a replacement process. For example, a preliminary stack of FIG. 21 including sacrificial layers alternately stacked with the insulating interlayers 7212 are formed. In the cell array region CA, the sacrificial layers are replaced with the gate lines 7211 through the slit to form the gate structure 7210. In this example, some of the sacrificial layers remain in regions of the stacked structure, for example, the pickup region PIA. The dielectric layers 7213 of the gate structure 7210 are the remaining sacrificial layers.

Contact holes extending through the insulating layers 7212 and the dielectric layers 7213 are formed. The insulating spacer 7230 are formed along an inner wall of the preliminary stack adjacent to each contact hole. The exposed dielectric layer at the bottom of the contact hole is etched to expand a lower end of the contact hole in a horizontal direction and expose the gate line 7211.

The conductive layer 7221 is formed in the contact hole, and the gap-fill layer 7222 and the contact pad 7223 are formed on the conductive layer 7221.

FIG. 23C is a cross-sectional view illustrating a semiconductor memory device in accordance with an embodiment.

Referring to FIG. 23C, the semiconductor memory device may include a gate structure 7310, a plurality of contact plugs 7320, insulating spacers 7330, and a plurality of support structures 7340.

The gate structure 7310 includes a plurality of gate lines 7311 alternately stacked with insulating interlayers 7312. The support structures 7340 extend through the gate structure 7310. The support structures 7340 may include at least one of an insulating material, a semiconductor material, and a conductive material.

Each of the contact plugs 7320 extends to a different depth and is connected to different gate line 7311.

The semiconductor memory device may be fabricated using a replacement process. For example, a preliminary stack PST, such as in FIG. 21,) is formed including sacrificial layers 104 alternately stacked with insulating interlayers 102. A contact hole is formed through the preliminary stack. A sacrificial pattern is formed in the contact hole. The sacrificial layers are replaced with the gate lines 7311 to form the gate structure 7310.

The sacrificial pattern is removed, and the insulating spacer 7330 is formed along an inner wall of the gate structure 7310 adjacent to each contact hole. A contact plugs 7340 is formed in each contact hole.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor memory system comprising:
a first chip; and
a second chip bonded to the first chip, the second chip including a memory cell array;
wherein the memory cell array of the second chip comprises:
a first stack including a source selection line;
a second stack disposed over the first stack, the second stack including a plurality of word lines stacked and insulated from each other;
a third stack disposed over the second stack, the third stack including a drain selection line; and
a channel structure including a first channel pillar formed through the first stack and the second stack, and a second channel pillar formed in the third stack and contacting the first channel pillar;
wherein a diameter of the second channel pillar is a smaller than a diameter of the first channel pillar.

2. The semiconductor memory system of claim 1, wherein the first structure includes:
a first substrate including a first surface and a second surface;
a first circuit layer integrated on the first surface of the first substrate, the first circuit layer including a plurality of transistors that form a peripheral circuit and a logic circuit; and
a first bonding layer disposed over the first circuit layer; and
wherein the second chip further includes a second bonding layer disposed over the memory cell array; and
wherein the first bonding layer of the first chip is bonded to the second bonding layer of the second chip.

3. The semiconductor memory system of claim 1, wherein the first channel pillar includes:
a first channel layer extending in the first direction; and
a second channel layer covering a first end of the first channel layer and contacting the second channel pillar;
wherein the second channel pillar contacts a center portion of the second channel layer.

4. The semiconductor memory system of claim 3, wherein an outer surface of the second channel layer is on a different plane than an outer surface of the second stack.

5. The semiconductor memory system of claim 3, wherein the channel structure further includes a memory layer between the first channel layer and the first stack and between the first channel layer and the second stack.

6. The semiconductor memory system of claim 3, wherein the memory cell array includes a plurality of second stacks that are stacked in the first direction, wherein the first channel layers of the second stacks extend continuously, and the first channel layers have angled sections at junctions between the plurality of second stacks.

7. The semiconductor memory system of claim 1, wherein the third stack further includes a gate insulating layer between a surface of the second stack and the second selection line, between the drain selection line and the first channel pillar, and between the drain selection line and the second channel pillar.

8. The semiconductor memory system of claim 1, further comprising a contact plug contacting the second channel pillar.

9. The semiconductor memory system of claim 8, wherein the second channel pillar comprises a first end contacting the first channel pillar, and a second end contacting the contact plug; and
wherein the second end of the second channel pillar includes a junction region with conductive dopants; and
wherein a surface and a sidewall of the end of the second channel pillar is disposed within the contact plug.

10. The semiconductor memory system of claim 1, wherein the third stack further includes an isolation layer extending through the second selection line; and
wherein the isolation layer divides the second selection line into second selection patterns configured to receive different signals.

11. The semiconductor memory system of claim 10, further comprising a drain selection line contact plugs, each contacting a corresponding one of the drain selection patterns; and
wherein the isolation layer is positioned between two consecutive drain selection line contact plugs.

12. The semiconductor memory system of claim 1, further comprising an additional structure disposed over a second surface of the second chip,
wherein the additional structure includes a second surface source layer electrically connected to the channel structures, and an external pad electrically connected to at least one of electrical components of the first chip and the second chip.

13. A method of manufacturing a semiconductor memory system, the method comprising:
preparing a first structure including a first substrate and a first circuit layer;
preparing a second structure including a memory cell array; and
bonding the second structure to the first structure, wherein preparing the second structure comprises:
forming a first preliminary stack over a second substrate by alternately and repeatedly stacking a first interlayer insulating layer with a sacrificial layer to form a first selection line;
forming a second preliminary stack on the first preliminary stack by alternately and repeatedly stacking insulating interlayers with sacrificial layers to form word lines;
forming a first channel pillar through the second preliminary stack and the first preliminary stack;
forming a second channel pillar on the first channel pillar, the second channel pillar having a smaller diameter than a diameter of the first channel pillar;
forming a gate insulating layer along an outer surface of the second preliminary stack, an outer surface of the first channel pillar, and a sidewall of the second channel pillar; and
forming a second selection line on the gate insulating layer to form a third stack.

14. The method of claim 13, further comprising:
grinding a second surface of the second substrate to expose the first channel pillar after the first structure is bonded to the second structure; and
forming a source layer contacting the exposed first channel pillar to form a third structure.

15. The method of claim 13, wherein forming the second channel pillar includes:
forming a mold layer over the second preliminary stack in which the first channel pillar is formed;
etching the mold layer to expose an end of the first channel pillar and to form a mold hole in the mold layer;
forming the second channel pillar in the mold hole; and
removing the mold layer.

16. The method of claim 13, further comprising:
forming an isolation layer extending through the second selection line to separate a plurality of second selection patterns electrically isolated by the isolation layer,
wherein the second selection patterns receive different signals.

17. The method of claim 16, wherein preparing the second structure further includes forming a contact plug that contacts an end of the second channel pillar, and forming second selection pattern-contact plugs that contact the second selection patterns.

18. The method of claim 17, wherein forming the contact plugs and the second selection pattern-contact plugs includes:
forming at least one interlayer insulating layer on the second channel pillar and the second selection line;
etching the interlayer insulating layer to form a first hole through which the end of the second channel pillar is exposed and second holes through which the second selection patterns are exposed;
forming a junction region in the end of the second channel pillar; and
filling a conductive material in the first hole and the second holes.

19. The method of claim 13, further comprising:
forming a memory layer between the first channel pillar and the first preliminary stack and the second preliminary stack.

20. The method of claim 13, further comprising replacing the sacrificial layers with conductive layers to form the first stack and the second stack.

21. The method of claim 13, wherein preparing the first structure comprises forming a first bonding layer over the first circuit layer;
wherein preparing the second structure comprises forming a second bonding layer over the memory cell array; and
wherein the first structure is hybrid bonded to the second structure.

22. A semiconductor memory system comprising:
a first structure including a peripheral circuit layer;
a second structure stacked over and bonded to the first structure, the second structure including a memory cell array, the second structure including a first side and a second side; and
a third structure disposed over the second side of the second structure, the third structure including a first interconnection electrically connected to the first structure and a second interconnection electrically connected to the second structure;
wherein the memory cell array includes:
a first stack near the second side of the second structure, the first stack including a plurality of first selection lines stacked and insulated from each other;
a second stack disposed over the first stack, the second stack including a plurality of word lines stacked and insulated from each other;
a third stack disposed over the second stack, the third stack including a second selection line; and
a channel structure including a first channel pillar formed through the first stack and the second stack, and a second channel pillar contacting the first channel pillar and formed in the third stack, wherein a diameter of the second channel pillar is smaller than a diameter of the first channel pillar; and
an isolation layer configured to divide the second selection line into a plurality of second selection patterns.

23. The semiconductor memory system of claim 22, wherein the second interconnection of the third structure includes a second surface source layer in contact with the first channel pillar of the channel structure, and the first interconnection of the third structure includes a peripheral-contact electrically connected to the peripheral circuit layer.

24. The semiconductor memory system of claim 22, further comprising a contact plug in contact with the second channel pillar, and each of a plurality of second selection line contact plugs in contact with a different one of the second selection patterns.

25. The semiconductor memory system of claim 24, wherein the isolation layer is located between the second selection line contact plugs.

26. A semiconductor memory system comprising:
a first structure including a buffer memory device and a peripheral circuit layer;
a second structure stacked over and bonded to the first structure, the second structure including a memory cell array, the second structure including a first side and a second side; and
a third structure disposed over the second side of the second structure, the third structure including a first interconnection electrically connected to the first structure and a second interconnection electrically connected to the second structure;
wherein the memory cell array includes:
a first stack near the second side of the second structure, the first stack including a plurality of first selection lines stacked and insulated from each other;
a second stack disposed over the first stack, the second stack including a plurality of word lines stacked and insulated from each other;
a third stack disposed over the second stack, the third stack including a plurality of second selection patterns located in one plane and electrically isolated from each other by an isolation layer;
a channel structure including a first channel pillar formed through the second stack and the first stack, and a second channel pillar contacting the first channel pillar, wherein a diameter of the second channel pillar is smaller than a diameter of the first channel pillar; and
a contact plug contacting an end of the second channel pillar and electrically connected to a bit line;
wherein the isolation layer is located between consecutive second channel pillars.

27. The semiconductor memory system of claim 26, further comprising a plurality of second selection line contact plugs, each contacting a different one of the second selection patterns; and
wherein the isolation layer is located between two consecutive contact plugs of the plurality of second selection line contact plugs.

28. A semiconductor memory device having a memory cell array region, the semiconductor memory device comprising:
a first stack including at least one first selection line;
at least one second stack stacked over the first stack, the second stack including a plurality of word lines stacked and insulated from each other;
a third stack disposed over the second stack, the third stack including a plurality of second selection patterns electrically isolated from each other by an isolation layer; and
a channel structure including a first channel pillar formed through the second stack and the first stack, and a second channel pillar in contact with a surface of the first channel pillar, wherein a diameter of the second channel pillar is a smaller than a diameter of the first channel pillar,
wherein the first selection line and the plurality of word lines in the memory cell array region have the same length in a first direction; and
wherein the second selection patterns in the memory cell array region have a shorter length in the first direction than the length of the first selection line and the plurality of word lines in the memory cell array region.

29. The semiconductor memory device of claim 28, further comprising a plurality of second selection line contact plugs, each one contacting a different one of the second selection patterns.

30. The semiconductor memory device of claim 28, wherein the second selection line contact plugs are located within the memory cell array region, and the isolation layer is located between the second selection line contact plugs.

31. The semiconductor memory device of claim 28, further comprising a pickup region located to a side of the memory cell array region;
wherein the first selection line, the plurality of word lines, and the second selection patterns, which extend in parallel in a first direction from the cell array region, are disposed on the pickup region; and
wherein the first selection line, the plurality of word lines, and the second selection patterns in the pickup region have progressively different lengths in the first direct and a second direction.

32. The semiconductor memory device of claim 28, wherein each of a plurality of contact plugs are electrically coupled to a different one of the first selection line, the plurality of word lines, and the second selection patterns; and
wherein each of the plurality of contact plugs have different heights within the pickup region.

33. A semiconductor memory system comprising:
a first structure; and
a second structure stacked on the first structure, the second structure including a memory cell array,
wherein the memory cell array comprises:
a first stack including a first selection line;
a second stack disposed over the first stack and including a plurality of spaced apart and insulated second selection lines;
a third stack disposed over the second stack and including a divided third selection line; and
a channel structure including a first channel pillar formed through the first stack and the second stack and a second channel pillar formed in the third stack and contacting the first channel pillar.

34. The semiconductor memory system of claim 33, wherein the first structure includes a first bonding layer, and the second structure includes a second bonding layer; and
wherein the first bonding layer of the first structure is bonded to the second bonding layer of the second structure to form a bonding interface.
